(19) United States
(12) Patent Application Publication
(10) Pub. No.: US 2025/0074041 A1
(43) Pub. Date: Mar. 6, 2025

(54) FILM, LAMINATE, WIRING BOARD, LAMINATED WIRING BOARD, AND MANUFACTURING METHOD OF LAMINATED WIRING BOARD

(71) Applicant: FUJIFILM Corporation, Tokyo (JP)

(72) Inventors: Akira YAMADA, Kanagawa (JP); Takeo KIDO, Kanagawa (JP)

(73) Assignee: FUJIFILM Corporation, Tokyo (JP)

(21) Appl. No.: 18/953,072

(22) Filed: Nov. 20, 2024

Related U.S. Application Data
(63) Continuation of application No. PCT/JP2023/016329, filed on Apr. 25, 2023.

(30) Foreign Application Priority Data
May 30, 2022 (JP) 2022-087675

(51) Int. Cl. B32B 27/32; B32B 15/08; B32B 27/08

(52) U.S. Cl. CPC B32B 27/32; B32B 15/08; B32B 27/08; B32B 2250/03; B32B 2250/24; B32B 2307/204; B32B 2307/51; B32B 2307/7376; B32B 2457/08

(57) ABSTRACT

Provided are a film including a layer A; and a layer B disposed on at least one surface of the layer A, in which a ratio of an clastic modulus EB of the layer B at 160° C. to an elastic modulus EA of the layer A at 160° C. is 1.0×10⁻⁶ or more, and a dielectric loss tangent is 0.005 or less.

### CROSS-REFERENCE TO RELATED APPLICATION

This application is a Continuation of International Application No. PCT/JP2023/016329, filed Apr. 25, 2023, which claims priority to Japanese Patent Application No. 2022-087675 filed May 30, 2022. Each of the above applications is hereby expressly incorporated by reference, in its entirety, into the present application.

### BACKGROUND OF THE INVENTION

### 1. Field of the Invention

The present disclosure relates to a film, a laminate, a wiring board, a laminated wiring board, and a manufacturing method of a laminated wiring board.

### 2. Description of the Related Art

In recent years, frequencies used in communication equipment tend to be extremely high. In order to suppress transmission loss in a high frequency band, insulating materials used in a circuit board are required to have a lowered relative permittivity and a lowered dielectric loss tangent.

For example, WO2016/170779A describes a method for producing a metal-clad laminated plate in which a metal sheet is bonded to at least one surface of a thermoplastic liquid crystal polymer film capable of forming an optically anisotropic molten phase, in which a laminated plate is formed by bonding the thermoplastic liquid crystal polymer film and the metal sheet, and the laminated plate is subjected to a heat treatment satisfying conditions (1) and (2). The condition (1) is a condition that the heat treatment temperature is a temperature of 1° C. or higher and 50° C. or lower from the melting point of the thermoplastic liquid crystal polymer film, and the condition (2) is a condition that the time of the heat treatment is 1 second or longer and 10 minutes or shorter. JP2019-199612A discloses a resin composition including a styrene-based polymer, an inorganic filler, and a curing agent, in which the styrene-based polymer is an acid-modified styrene-based polymer having a carboxyl group, the inorganic filler is silica and/or aluminum hydroxide, a particle diameter of the inorganic filler is 1 μm or less, a content of the inorganic filler is 20 to 80 parts by mass with respect to 100 parts by mass of the styrene-based polymer, and the resin composition satisfies specific Expressions (A) and (B) in a form of a film having a thickness of 25 μm.

### SUMMARY OF THE INVENTION

According to the embodiment of the present invention, a film having a low dielectric loss tangent and excellent step followability is provided.

In addition, according to another embodiment of the present invention, there are provided a laminate, a wiring board, a laminated wiring board, and a manufacturing method of a laminated wiring board, in which the film is used.

The present disclosure includes the following aspects.
<1> A film including: a layer A; and a layer B disposed on at least one surface of the layer A, in which a ratio of an elastic modulus EB of the layer B at 160° C. to an elastic modulus EA of the layer A at 160° C. is 1.0×10⁻⁶ or more, and a dielectric loss tangent is 0.005 or less.
<2> The film according to <1>, in which the elastic modulus EB is 0.1 GPa or less.
<3> The film according to <1> or <2>, in which the ratio of the elastic modulus EB to the elastic modulus EA is 0.1 or less.
<4> The film according to any one of <1> to <3>, in which an average thickness of the layer B is 15 μm or less.
<5> The film according to any one of <1> to <4>, in which the layer A contains a liquid crystal polymer.
<6> The film according to any one of <1> to <5>, in which a melting point of the layer A is 315° C. or higher.
<7> The film according to any one of <1> to <6>, in which the layer A contains a polyolefin.
<8> The film according to <7>, in which a content of the polyolefin is 5% by mass to 30% by mass with respect to a total mass of the layer A.
<9> The film according to any one of <1> to <8>, in which the layer B contains a cured substance of a composition containing a polymer and a compound having a reactive group.
<10> The film according to any one of <1> to <9>, further including a layer C, in which the layer C, the layer A, and the layer B are arranged in this order.
<11> The film according to <10>, in which an average thickness of the layer Cis 15 μm or less.
<12> The film according to <10> or <11>, in which the layer C contains a cured substance of a polymer and a compound having a reactive group.
<13> A laminate including: the film according to any one of <1> to <12>; and a metal layer disposed on at least one surface of the film.
<14> A wiring board comprising: the film according to any one of <1> to <12>; a metal wire disposed on one surface of the film; and a metal layer disposed on the other surface of the film.
<15> A laminated wiring board including, in the following order: a first metal layer; a first film according to any one of <1> to <12>; a metal wire; a second film according to any one of <1> to <12>; and a second metal layer, in which the metal wire is embedded in a part of the first film and the second film.
<16> A manufacturing method of a laminated wiring board, including: a step of manufacturing a laminate including the first film according to any one of <1> to <12> and a first metal layer disposed on one surface of the first film; a step of manufacturing a wiring board including the second film according to any one of <1> to <12>, a metal wire disposed on one surface of the second film, and a second metal layer disposed on the other surface of the second film; and a step of superimposing the laminate and the wiring board such that both the first metal layer and the second metal layer are outermost surfaces and subjecting the laminate and the wiring board to thermal compression bonding.

According to the embodiment of the present invention, a film having a low dielectric loss tangent and excellent step followability is provided.

In addition, according to another embodiment of the present invention, there are provided a laminate, a wiring board, a laminated wiring board, and a manufacturing method of a laminated wiring board, in which the film is used.

### DESCRIPTION OF THE PREFERRED EMBODIMENTS

Hereinafter, the content of the present disclosure will be described in detail. The description of configuration requirements below is made based on representative embodiments of the present disclosure in some cases, but the present disclosure is not limited to such embodiments.

In the present disclosure, a numerical range expressed using “to” includes numerical values listed before and after “to” as the lower limit value and the upper limit value.

In a numerical range described in a stepwise manner in the present disclosure, an upper limit value or a lower limit value described in one numerical range may be replaced with an upper limit or a lower limit in another numerical range described in a stepwise manner. In addition, in a range of numerical values described in the present disclosure, the upper limit value or the lower limit value of the range of numerical values may be replaced with values illustrated in the examples.

In addition, in the present disclosure, in a case where there is no description regarding whether a group (atomic group) is substituted or unsubstituted, such a group includes both a group having no substituent and a group having a substituent. For example, the concept of an “alkyl group” includes not only an alkyl group that does not have a substituent (unsubstituted alkyl group) but also an alkyl group having a substituent (substituted alkyl group).

In the present disclosure, “(meth)acryl” is a term used to explain a concept including both the acryl and methacryl, and “(meth)acryloyl” is a term used to explain a concept including both the acryloyl and methacryloyl.

In addition, the term “step” in the present disclosure means not only an independent step but also a step that cannot be clearly differentiated from other steps as long as the intended goal of the step is achieved. Further, in the present disclosure, “% by mass” has the same definition as that for “% by weight”, and “part by mass” has the same definition as that for “part by weight”.

Furthermore, in the present disclosure, a combination of two or more preferred embodiments is a more preferred embodiment.

In addition, the weight-average molecular weight (Mw) and the number-average molecular weight (Mn) in the present disclosure are molecular weights converted using polystyrene as a standard substance by performing detection with a gel permeation chromatography (GPC) analysis apparatus using TSKgel SuperHM-H (trade name, manufactured by Tosoh Corporation) column, a solvent of pentafluorophenol (PFP) and chloroform at a mass ratio of 1:2, and a differential refractometer, unless otherwise specified.

In the present disclosure, in a case where the film has a long shape, a width direction means a short hand direction and a transverse direction (TD) of the film, and a length direction means a longitudinal direction and a machine direction (MD) of a film material.

### [Film]

The film according to the present disclosure includes a layer A; and a layer B disposed on at least one surface of the layer A, in which a ratio of an elastic modulus EB of the layer B at 160° C. to an elastic modulus EA of the layer A at 160° C. is 1.0×10⁻⁶ or more, and a dielectric loss tangent is 0.005 or less.

As a result of intensive studies, the present inventors have found that a film having excellent step followability can be provided by adopting the above configuration. In addition, the “step followability” in the present disclosure means a characteristic of being easily deformed following a step and easily holding a shape after the deformation.

In the film according to the embodiment of the present disclosure, since the ratio of the elastic modulus EB of the layer B at 160° C. to the elastic modulus EA of the layer A at 160° C. is 1.0×10⁻⁶ or more, the layer B is not too flexible. Therefore, for example, in a case where the metal wire and the film in the wiring board are bonded to each other, the film is deformed following the step of the metal wire and is held in the deformed state. That is, the film according to the present disclosure is excellent in step followability.

On the other hand, the thermoplastic liquid crystal polymer film described in WO2016/170779A needs to be heated at a high temperature in order to be deformed, and the thermoplastic liquid crystal polymer flows due to the heating at a high temperature, so that the film is not easily held in a deformed state. In addition, JP2019-199612A does not describe the aspect of the step followability.

### <Ratio of Clastic Modulus EB of Layer B at 160° C. to Clastic Modulus EA of Layer A at 160° C.>

In the film according to the embodiment of the present disclosure, a ratio of the elastic modulus EB of the layer B at 160° C. to the elastic modulus EA of the layer A at 160° C. (that is, clastic modulus EB/elastic modulus EA) is 1.0×10⁻⁶ or more. In a case where the ratio is 1.0×10⁻⁶ or more, the layer B is not excessively soft and is excellent in step followability. From the viewpoint of further improving the step followability, the above-described ratio is preferably 1.0×10⁻⁴ or more and more preferably 1.0×10⁻³ or more.

In addition, from a viewpoint of further improving the step followability, the above ratio is preferably 0.1 or less, more preferably 0.05 or less, and still more preferably 0.01 or less.

The elastic modulus in the present disclosure is measured by the following method.

The elastic moduli at 160° C. for layer A and the following layer B, which constitute the laminate, are indentation clastic moduli determined by measuring the elastic modulus of each layer in a cross-section obtained by cutting the laminated body along the thickness direction under a temperature environment of 160° C., using a nanoindenter according to the method described in ISO 14577. A measuring method of the elastic modulus of each layer will be described in Examples which will be described later.

### <Dielectric Loss Tangent>

From the viewpoint of reducing transmission loss, in the film according to the present disclosure, the dielectric loss tangent is 0.005 or less, preferably 0.002 or less, and more preferably greater than 0 and 0.001 or less.

In the present disclosure, the dielectric loss tangent is measured by the following method.

The dielectric loss tangent is measured by a resonance perturbation method at a frequency of 10 GHz. A 10 GHz cavity resonator (CP531 of Kanto Electronics Application & Development Inc.) is connected to a network analyzer (“E8363B” manufactured by Agilent Technology), and a measurement sample (width: 2.0 mm×length: 80 mm) is inserted into the cavity resonator, and the dielectric loss tangent of the measurement sample is measured based on a change in resonance frequency for 96 hours before and after the insertion in an environment of a temperature of 25° C. and a humidity of 60% RH.

### <Layer A>

The film according to the embodiment of the present disclosure has a layer A.

Examples of a method for detecting or determining the layer configuration and the thickness of each layer in the film include the following methods.

First, a cross-sectional sample of the polymer film is cut out by a microtome, and a layer configuration and a thickness of each layer are determined with an optical microscope. In a case where the determination with an optical microscope is difficult, the determination may be obtained by performing morphological observation with a scanning electron microscope (SEM), component analysis with a time-of-flight secondary ion mass spectrometry (TOF-SIMS), or the like.

The elastic modulus EA of the layer A at 160° C. is preferably 2.0 GPa or less and more preferably 1.0 GPa or less. In a case where the elastic modulus EA of the layer A at 160° C. is small, the layer A can be deformed following the step together with the layer B, and the step followability of the entire film is improved. The lower limit value of the clastic modulus EA is not particularly limited, and is, for example, 0.1 GPa.

From the viewpoint of wiring processing suitability and lamination processing suitability, the melting point of the layer A is preferably 315° C. or higher and more preferably 320° C. or higher. The upper limit value of the melting point is not particularly limited, and is, for example, 380° C.

In the present disclosure, the melting point is measured using a differential scanning calorimetry device.

From the viewpoint of transmission loss of the film, the dielectric loss tangent of the layer A is preferably 0.004 or less, more preferably 0.002 or less, still more preferably 0.0015 or less, and particularly preferably greater than 0 and 0.001.

The components constituting the layer A are not particularly limited as long as the elastic modulus EA and the elastic modulus EB can satisfy the above-described ratio. Since the layer A easily satisfies the above ratio, it is preferable that the layer A contains at least one polymer.

The type of the polymer is not particularly limited, and a known polymer can be used.

Examples of the polymer include thermoplastic resins such as a liquid crystal polymer, a fluororesin, a polymerized substance of a compound which has a cyclic aliphatic hydrocarbon group and a group having an ethylenically unsaturated bond, polyether ether ketone, polyolefin, polyamide, polyester, polyphenylene sulfide, polyether ketone, polycarbonate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide, and a cyanate resin.

Among these, from the viewpoint of reducing the dielectric loss tangent of the film, the layer A preferably contains at least one polymer selected from the group consisting of a liquid crystal polymer, a fluororesin, a polymer of a compound having a cyclic aliphatic hydrocarbon group and a group having an ethylenically unsaturated bond, and a polyphenylene ether, more preferably contains at least one polymer selected from the group consisting of a liquid crystal polymer and a fluororesin, particularly preferably contains a liquid crystal polymer from the viewpoint of film forming properties and mechanical strength, and particularly preferably contains a fluororesin from the viewpoint of the dielectric loss tangent.

### —Liquid Crystal Polymer—

The type of the liquid crystal polymer is not particularly limited, and a known liquid crystal polymer can be used.

In addition, the liquid crystal polymer may be a thermotropic liquid crystal polymer which exhibits liquid crystallinity in a molten state, or may be a lyotropic liquid crystal polymer which exhibits liquid crystallinity in a solution state. In addition, in a case of the thermotropic liquid crystal, it is preferable that the liquid crystal is melted at a temperature of 450° C. or lower.

Examples of the liquid crystal polymer include a liquid crystal polyester, a liquid crystal polyester amide in which an amide bond is introduced into the liquid crystal polyester, a liquid crystal polyester ether in which an ether bond is introduced into the liquid crystal polyester, and a liquid crystal polyester carbonate in which a carbonate bond is introduced into the liquid crystal polyester.

In addition, as the liquid crystal polymer, from the viewpoint of liquid crystallinity, a polymer having an aromatic ring is preferable, and an aromatic polyester or an aromatic polyester amide is more preferable.

Furthermore, the liquid crystal polymer may be a polymer in which an imide bond, a carbodiimide bond, a bond derived from an isocyanate, such as an isocyanurate bond, or the like is further introduced into the aromatic polyester or the aromatic polyester amide.

In addition, it is preferable that the liquid crystal polymer is a wholly aromatic liquid crystal polymer formed of only an aromatic compound as a raw material monomer.

Examples of the liquid crystal polymer include the following liquid crystal polymers.
1) a liquid crystal polymer obtained by polycondensing (i) an aromatic hydroxycarboxylic acid, (ii) an aromatic dicarboxylic acid, and (iii) at least one compound selected from the group consisting of an aromatic diol, an aromatic hydroxyamine, and an aromatic diamine;
2) a liquid crystal polymer obtained by polycondensing a plurality of types of aromatic hydroxycarboxylic acids;
3) a liquid crystal polymer obtained by polycondensing (i) an aromatic dicarboxylic acid and (ii) at least one compound selected from the group consisting of an aromatic diol, an aromatic hydroxyamine, and an aromatic diamine;
4) a liquid crystal polymer obtained by polycondensing (i) polyester such as polyethylene terephthalate and (ii) an aromatic hydroxycarboxylic acid.

Here, the aromatic hydroxycarboxylic acid, the aromatic dicarboxylic acid, the aromatic diol, the aromatic hydroxyamine, and the aromatic diamine may be each independently replaced with a polycondensable derivative.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polymerizable derivative of a compound having a hydroxy group, such as an aromatic hydroxycarboxylic acid, an aromatic diol, and an aromatic hydroxyamine, include a derivative (acylated product) obtained by acylating a hydroxy group and converting the acylated group into an acyloxy group.

For example, the aromatic hydroxycarboxylic acid, the aromatic diol, and the aromatic hydroxyamine can be each replaced with an acylated product by acylating a hydroxy group and converting the acylated group into an acyloxy group.

Examples of a polymerizable derivative of a compound having an amino group, such as an aromatic hydroxyamine or an aromatic diamine, include a derivative (acylated product) obtained by acylating an amino group and converting the acylated group to an acylamino group.

For example, the aromatic hydroxyamine and the aromatic diamine can be each replaced with an acylated product by acylating an amino group and converting the acylated group into an acylamino group.

The liquid crystal polymer is preferably a polymer having crystallinity (for example, aromatic polyester amide described later). In a case where the liquid crystal polymer has crystallinity, the dielectric loss tangent is further reduced.

A melting point of the liquid crystal polymer is preferably equal to or higher than 250° C., more preferably 250° C. to 350° C., and still more preferably 260° C. to 330° C.

The weight-average molecular weight of the liquid crystal polymer is preferably equal to or less than 1,000,000, more preferably 3,000 to 300,000, still more preferably 5,000 to 100,000, and particularly preferably 5,000 to 30,000.

The liquid crystal polymer preferably includes aromatic polyester amide from a viewpoint of further decreasing the dielectric loss tangent. Aromatic polyester amide is resin having at least one aromatic ring and having an ester bond and an amide bond. Aromatic polyester amide included in a resin layer is preferably fully aromatic polyester amide among the substances from a viewpoint of heat resistance.

Aromatic polyester amide preferably contains a constitutional unit represented by Formula 1, a constitutional unit represented by Formula 2, and a constitutional unit represented by Formula 3.

—O—Ar¹—CO— Formula 1

—CO—Ar²—CO— Formula 2

—NH—Ar³—O— Formula 3

In Formula 1 to Formula 3, Ar¹, Ar², and Ar³ each independently represent a phenylene group, a naphthylene group, or a biphenylylene group.

Hereinafter, the constitutional unit represented by Formula 1 and the like are also referred to as “unit 1” and the like.

The unit 1 can be introduced, for example, using aromatic hydroxycarboxylic acid as a raw material.

The unit 2 can be introduced, for example, using aromatic dicarboxylic acid as a raw material.

The unit 3 can be introduced, for example, using aromatic hydroxylamine as a raw material.

Here, the aromatic hydroxycarboxylic acid, the aromatic dicarboxylic acid, the aromatic diol, and the aromatic hydroxylamine may be each independently replaced with a polycondensable derivative.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polymerizable derivative of a compound having a hydroxy group, such as an aromatic hydroxycarboxylic acid and an aromatic hydroxyamine, include a derivative (acylated product) obtained by acylating a hydroxy group and converting the acylated group into an acyloxy group.

For example, the aromatic hydroxycarboxylic acid and the aromatic hydroxylamine can be each replaced with an acylated product by acylating a hydroxy group and converting the acylated group into an acyloxy group.

Examples of a polycondensable derivative of the aromatic hydroxylamine include a substance (acylated product) obtained by acylating an amino group to convert the amino group into an acylamino group.

For example, the aromatic hydroxyamine can be replaced with an acylated product by acylating an amino group and converting the acylated group into an acylamino group.

In Formula 1, Ar¹ is preferably a p-phenylene group, a 2,6-naphthylene group, or a 4,4′-biphenylylene group, and more preferably a 2,6-naphthylene group.

In a case where Ar¹ is a p-phenylene group, the unit 1 is, for example, a constitutional unit derived from p-hydroxybenzoic acid.

In a case where Ar is a 2,6-naphthylene group, the unit 1 is, for example, a constitutional unit derived from 6-hydroxy-2-naphthoic acid.

In a case where Ar¹ is a 4,4′-biphenylylene group, the unit 1 is, for example, a constitutional unit derived from 4′-hydroxy-4-biphenylcarboxylic acid.

In Formula 2, Ar² is preferably a p-phenylene group, an m-phenylene group, or a 2,6-naphthylene group, and more preferably an m-phenylene group.

In a case where Ar² is a p-phenylene group, the unit 2 is, for example, a constitutional unit derived from terephthalic acid.

In a case where Ar² is an m-phenylene group, the unit 2 is, for example, a constitutional unit derived from isophthalic acid.

In a case where Ar² is a 2,6-naphthylene group, the unit 2 is, for example, a constitutional unit derived from 2,6-naphthalenedicarboxylic acid.

In Formula 3, Ar³ is preferably a p-phenylene group or a 4,4′-biphenylylene group, and more preferably a p-phenylene group.

In a case where Ar³ is a p-phenylene group, the unit 3 is, for example, a constitutional unit derived from p-aminophenol.

In a case where Ar³ is a 4,4′-biphenylylene group, the unit 3 is, for example, a constitutional unit derived from 4-amino-4′-hydroxybiphenyl.

With respect to the total content of the unit 1, the unit 2, and the unit 3, a content of the unit 1 is preferably 30 mol % or more, a content of the unit 2 is preferably 35% or less, and a content of the unit 3 is preferably 35 mol % or less.

The content of the unit 1 is preferably 30 mol % to 80 mol %, more preferably 30 mol % to 60 mol %, and particularly preferably 30 mol % to 40 mol % with respect to the total content of the unit 1, the unit 2, and the unit 3.

The content of the unit 2 is preferably 10 mol % to 35 mol %, more preferably 20 mol % to 35 mol %, and particularly preferably 30 mol % to 35 mol % with respect to the total content of the unit 1, the unit 2, and the unit 3.

The content of the unit 3 is preferably 10 mol % to 35 mol %, more preferably 20 mol % to 35 mol %, and particularly preferably 30 mol % to 35 mol % with respect to the total content of the unit 1, the unit 2, and the unit 3.

The total content of the constitutional units is a value obtained by totaling a substance amount (mol) of each constitutional unit. The substance amount of each constitutional unit is calculated by dividing a mass of each constitutional unit constituting aromatic polyester amide by a formula weight of each constitutional unit.

In a case where a ratio of the content of the unit 2 to the content of the unit 3 is expressed as [Content of unit 2]/[Content of unit 3] (mol/mol), the ratio is preferably 0.9/1 to 1/0.9, more preferably 0.95/1 to 1/0.95, and still more preferably 0.98/1 to 1/0.98.

Aromatic polyester amide may have two kinds or more of the unit 1 to the unit 3 each independently. Alternatively, aromatic polyester amide may have other constitutional units other than the unit 1 to the unit 3. A content of other constitutional units is preferably 10 mol % or less and more preferably 5 mol % or less with respect to the total content of all constitutional units.

Aromatic polyester amide is preferably produced by subjecting a source monomer corresponding to the constitutional unit constituting the aromatic polyester amide to melt polymerization.

The layer A may include only one or two or more kinds of aromatic polyester amides.

A content of aromatic polyester amide is preferably equal to or greater than 50% by mass, more preferably equal to or greater than 70% by mass, and still more preferably equal to or greater than 90% by mass, with respect to a total amount of the layer A. An upper limit value of the content of aromatic polyester amide is not particularly limited, and may be 100% by mass.

It is preferable that the liquid crystal polymer is produced by melt-polymerizing raw material monomers corresponding to the constitutional units constituting the liquid crystal polymer. The melt polymerization may be carried out in the presence of a catalyst, examples of the catalyst include metal compounds such as magnesium acetate, stannous acetate, tetrabutyl titanate, lead acetate, sodium acetate, potassium acetate, and antimony trioxide, and nitrogen-containing heterocyclic compounds such as 4-(dimethylamino)pyridine and 1-methylimidazole, and nitrogen-containing heterocyclic compounds are preferably used. The melt polymerization may be further carried out by solid phase polymerization as necessary.

A flow start temperature of the liquid crystal polymer is preferably 250° C. or higher, more preferably 250° C. or higher and 350° C. or lower, and still more preferably 260° C. or higher and 330° C. or lower. In a case where the flow start temperature of the liquid crystal polymer is within the above-described range, the solubility, the heat resistance, the strength, and the rigidity are excellent, and the viscosity of the solution is appropriate.

The flow start temperature, also referred to as a flow temperature, is a temperature at which a viscosity of 4,800 Pa·s (48,000 poises) is exhibited in a case where the liquid crystal polymer is melted and extruded from a nozzle having an inner diameter of 1 mm and a length of 10 mm while the temperature is raised at a rate of 4° C./min under a load of 9.8 MPa (100 kg/cm²) using a capillary rheometer and is a guideline for the molecular weight of the liquid crystal polymer (see p. 95 of “Liquid Crystal Polymers-Synthesis/Molding/Applications-”, written by Naoyuki Koide, CMC Corporation, Jun. 5, 1987).

### —Fluororesin—

In the present disclosure, the type of the fluororesin is not particularly limited, and a known fluororesin can be used.

Examples of the fluororesin include a homopolymer and a copolymer containing a constitutional unit derived from a fluorinated α-olefin monomer, that is, an α-olefin monomer containing at least one fluorine atom. In addition, examples of the fluororesin include a copolymer containing a constitutional unit derived from a fluorinated α-olefin monomer, and a constitutional unit derived from a non-fluorinated ethylenically unsaturated monomer reactive to the fluorinated α-olefin monomer.

Examples of the fluorinated α-olefin monomer include CF₂═CF₂, CHF═CF₂, CH₂—CF₂, CHCl═CHF, CCIF═CF₂, CCl₂═CF₂, CCIF═CCIF, CHF═CCl₂, CH₂═CCIF, CCl₂═CCIF, CF₃CF═CF₂, CF₃CF═CHF, CF₃CH═CF₂, CF₃CH═CH₂, CHF₂CH═CHF, CF₃CF═CF₂, and perfluoro (alkyl having 2 to 8 carbon atoms) vinyl ether (for example, perfluoromethyl vinyl ether, perfluoropropyl vinyl ether, and perfluorooctyl vinyl ether). Among these, as the fluorinated α-olefin monomer, at least one monomer selected from the group consisting of tetrafluoroethylene (CF₂═CF₂), chlorotrifluoroethylene (CCIF═CF₂), (perfluorobutyl)ethylene, vinylidene fluoride (CH₂═CF₂), and hexafluoropropylene (CF₂═CFCF₃) is preferable.

Examples of the non-fluorinated ethylenically unsaturated monomer include ethylene, propylene, butene, and an ethylenically unsaturated aromatic monomer (for example, styrene and α-methylstyrene).

The fluorinated α-olefin monomer may be used alone or in combination of two or more thereof.

In addition, the non-fluorinated ethylenically unsaturated monomer may be used alone or in combination of two or more thereof.

Examples of the fluororesin include polychlorotrifluoroethylene (PCTFE), poly(chlorotrifluoroethylene-propylene), poly(ethylene-tetrafluoroethylene) (ETFE), poly(ethylene-chlorotrifluoroethylene) (ECTFE), poly(hexafluoropropylene), poly(tetrafluoroethylene) (PTFE), poly (tetrafluorocthylene-ethylene-propylene), poly(tetrafluoroethylene-hexafluoropropylene) (FEP), poly(tetrafluoroethylene-propylene) (FEPM), poly(tetrafluoroethylene-perfluoropropylene vinyl ether), poly(tetrafluoroethylene-perfluoroalkyl vinyl ether) (PFA) (for example, poly (tetrafluoroethylene-perfluoropropyl vinyl ether)), polyvinyl fluoride (PVF), polyvinylidene fluoride (PVDF), poly(vinylidene fluoride-chlorotrifluoroethylene), perfluoropolyether, perfluorosulfonic acid, and perfluoropolyoxetane.

The fluororesin may have a constitutional unit derived from fluorinated ethylene or fluorinated propylene.

The fluororesin may be used alone or in combination of two or more thereof.

The fluororesin is preferably FEP, PFA, ETFE, or PTFE.

The FEP is available from Du Pont as the trade name of TEFLON (registered trademark) FEP or from DAIKIN INDUSTRIES, LTD. as the trade name of NEOFLON FEP. The PFA is available from DAIKIN INDUSTRIES, LTD. as the trade name of NEOFLON PFA, from Du Pont as the trade name of TEFLON (registered trademark) PFA, or from Solvay Solexis as the trade name of HYFLON PFA.

The fluororesin more preferably includes PTFE. The PTFE may be a PTFE homopolymer, a partially modified PTFE homopolymer, or a combination including one or both of these. The partially modified PTFE homopolymer preferably contains a constitutional unit derived from a comonomer other than tetrafluoroethylene in an amount of less than 1% by mass based on the total mass of the polymer.

The fluororesin may be a crosslinkable fluoropolymer having a crosslinkable group. The crosslinkable fluoropolymer can be crosslinked by a known crosslinking method in the related art. One of the representative crosslinkable fluoropolymers is a fluoropolymer having (meth)acryloyloxy. For example, the crosslinkable fluoropolymer can be represented by the following formula.

H₂C═CR′COO—(CH₂)ₙ—R—(CH₂)ₙ—OOCR′═CH₂ Formula:

In the formula, R is an oligomer chain having a constitutional unit derived from the fluorinated α-olefin monomer, R′ is H or —CH₃, and n is 1 to 4. R may be a fluorine-based oligomer chain having a constitutional unit derived from tetrafluoroethylene.

In order to initiate a radical crosslinking reaction through the (meth)acryloyloxy group in the fluororesin, by exposing the fluoropolymer having a (meth)acryloyloxy group to a free radical source, a crosslinked fluoropolymer network can be formed. The free radical source is not particularly limited, and suitable examples thereof include a photoradical polymerization initiator and an organic peroxide. Appropriate photoradical polymerization initiators and organic peroxides are well known in the art. The crosslinkable fluoropolymer is commercially available, and examples thereof include Viton B manufactured by Du Pont.

—Polymerized Substance of Compound which has Cyclic Aliphatic Hydrocarbon Group and Group Having Ethylenically Unsaturated Bond—

Examples of the polymerized substance of a compound which has a cyclic aliphatic hydrocarbon group and a group having an ethylenically unsaturated bond include thermoplastic resins having a constitutional unit derived from a cyclic olefin monomer such as norbornene and a polycyclic norbornene-based monomer.

The polymerized substance of a compound which has a cyclic aliphatic hydrocarbon group and a group having an ethylenically unsaturated bond may be a ring-opened polymer of the above-described cyclic olefin, a hydrogenated product of a ring-opened copolymer using two or more cyclic olefins, or an addition polymer of a cyclic olefin and a linear olefin or aromatic compound having an ethylenically unsaturated bond such as a vinyl group. In addition, a polar group may be introduced into the polymerized substance of a compound which has a cyclic aliphatic hydrocarbon group and a group having an ethylenically unsaturated bond.

The polymerized substance of a compound which has a cyclic aliphatic hydrocarbon group and a group having an ethylenically unsaturated bond may be used alone or in combination of two or more thereof.

A ring structure of the cyclic aliphatic hydrocarbon group may be a single ring, a fused ring in which two or more rings are fused, or a crosslinked ring.

Examples of the ring structure of the cyclic aliphatic hydrocarbon group include a cyclopentane ring, a cyclohexane ring, a cyclooctane ring, an isophorone ring, a norbornane ring, and a dicyclopentane ring.

The compound which has a cyclic aliphatic hydrocarbon group and a group having an ethylenically unsaturated bond is not particularly limited, and examples thereof include a (meth)acrylate compound having a cyclic aliphatic hydrocarbon group, a (meth)acrylamide compound having a cyclic aliphatic hydrocarbon group, and a vinyl compound having a cyclic aliphatic hydrocarbon group. Among these, preferred examples thereof include a (meth)acrylate compound having a cyclic aliphatic hydrocarbon group. In addition, the compound which has a cyclic aliphatic hydrocarbon group and a group having an ethylenically unsaturated bond may be a monofunctional ethylenically unsaturated compound or a polyfunctional ethylenically unsaturated compound.

The number of cyclic aliphatic hydrocarbon groups in the compound which has a cyclic aliphatic hydrocarbon group and a group having an ethylenically unsaturated bond may be 1 or more, and may be 2 or more.

It is sufficient that the polymerized substance of a compound which has a cyclic aliphatic hydrocarbon group and a group having an ethylenically unsaturated bond is a polymer obtained by polymerizing at least one compound which has a cyclic aliphatic hydrocarbon group and a group having an ethylenically unsaturated bond, and it may be a polymerized substance of two or more kinds of the compound which has a cyclic aliphatic hydrocarbon group and a group having an ethylenically unsaturated bond or a copolymer with other ethylenically unsaturated compounds having no cyclic aliphatic hydrocarbon group.

In addition, the polymerized substance of a compound which has a cyclic aliphatic hydrocarbon group and a group having an ethylenically unsaturated bond is preferably a cycloolefin polymer.

### —Polyphenylene Ether—

In the polyphenylene ether, from the viewpoint of dielectric loss tangent and heat resistance, the average number of molecular terminal phenolic hydroxyl groups per molecule (the number of terminal hydroxyl groups) is preferably 1 to 5 and more preferably 1.5 to 3.

The number of terminal hydroxyl groups in the polyphenylene ether can be found, for example, from a standard value of a product of the polyphenylene ether. In addition, the number of terminal hydroxyl groups is expressed as, for example, an average value of the number of phenolic hydroxyl groups per molecule of all polyphenylene ethers present in 1 mol of the polyphenylene ether.

The polyphenylene ether may be used alone or in combination of two or more thereof.

Examples of the polyphenylene ether include a polyphenylene ether including 2,6-dimethylphenol and at least one of bifunctional phenol or trifunctional phenol, and poly(2,6-dimethyl-1,4-phenylene oxide). More specifically, the polyphenylene ether is preferably a compound having a structure represented by Formula (PPE).

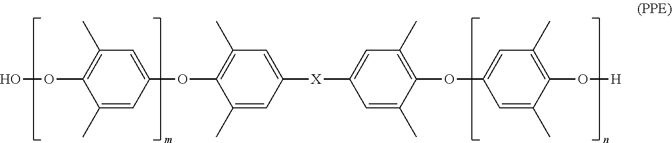

In Formula (PPE), X represents an alkylene group having 1 to 3 carbon atoms or a single bond, m represents an integer of 0 to 20, n represents an integer of 0 to 20, and the sum of m and n represents an integer of 1 to 30.

Examples of the alkylene group in X described above include a dimethylmethylene group.

In a case where heat curing is performed after film formation, from the viewpoint of heat resistance and film-forming property, a weight-average molecular weight (Mw) of the polyphenylene ether is preferably 500 to 5,000 and preferably 500 to 3,000. In addition, in a case where the heat curing is not performed, the weight-average molecular weight (Mw) of the polyphenylene ether is not particularly limited, but is preferably 3,000 to 100,000 and preferably 5,000 to 50,000.

### —Aromatic Polyether Ketone—

The aromatic polyether ketone is not particularly limited, and a known aromatic polyether ketone can be used.

The aromatic polyether ketone is preferably a polyether ether ketone.

The polyether ether ketone is one type of the aromatic polyether ketone, and is a polymer in which bonds are arranged in the order of an ether bond, an ether bond, and a carbonyl bond. It is preferable that the bonds are linked to each other by a divalent aromatic group. The aromatic polyether ketone may be used alone or in combination of two or more thereof.

Examples of the aromatic polyether ketone include polyether ether ketone (PEEK) having a chemical structure represented by Formula (P1), polyether ketone (PEK) having a chemical structure represented by Formula (P2), polyether ketone ketone (PEKK) having a chemical structure represented by Formula (P3), polyether ether ketone ketone (PEEKK) having a chemical structure represented by Formula (P4), and polyether ketone ether ketone ketone (PEKEKK) having a chemical structure represented by Formula (P5).

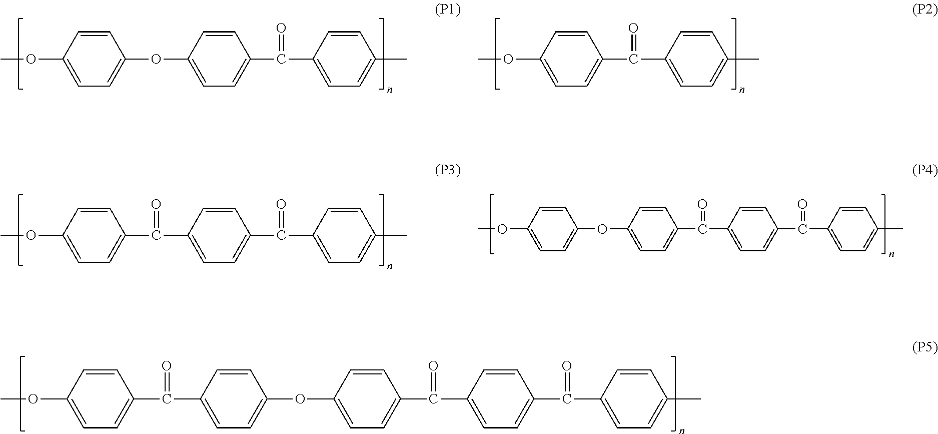

From the viewpoint of mechanical properties, each n of Formulae (P1) to (P5) is preferably 10 or more and more preferably 20 or more. On the other hand, from the viewpoint that the aromatic polyether ketone can be easily produced, n is preferably 5,000 or less and more preferably 1,000 or less. That is, n is preferably 10 to 5,000 and more preferably 20 to 1,000.

As described above, the layer A preferably contains at least one kind of liquid crystal polymer.

In a case where the layer A includes a liquid crystal polymer, from the viewpoint of the dielectric loss tangent of the film and the adhesiveness to the metal layer, the content of the liquid crystal polymer is preferably 20% by mass to 100% by mass, more preferably 50% by mass to 95% by mass, and particularly preferably 70% by mass to 90% by mass with respect to the total mass of the layer A.

### —Polyolefin—

From the viewpoint of further reducing the dielectric loss tangent, the layer A preferably further contains at least one polyolefin.

In the present disclosure, the polyolefin means a resin having a constitutional unit derived from an olefin.

The polyolefin may be linear or branched. In addition, the polyolefin may have a cyclic structure such as a polycycloolefin.

Examples of the polyolefin include polyethylene, polypropylene (PP), polymethylpentene (TPX and the like manufactured by Mitsui Chemicals, Inc.), hydrogenated polybutadiene, a cycloolefin polymer (COP, Zeonor and the like manufactured by ZEON Corporation), and a cycloolefin copolymer (COC, APEL and the like manufactured by Mitsui Chemicals, Inc.).

The polyethylene may be either high density polyethylene (HDPE) or low density polyethylene (LDPE). In addition, the polyethylene may be linear low density polyethylene (LLDPE).

The polyolefin may be a copolymer of an olefin and a monomer other than the olefin, such as acrylate, methacrylate, styrene, and/or a vinyl acetate-based monomer.

Examples of the polyolefin as the copolymer include a styrene-ethylene/butylene-styrene copolymer (SEBS). SEBS may be hydrogenated.

However, from the viewpoint that the effects of the present disclosure are more excellent, the content of the constitutional unit derived from a monomer other than an olefin is preferably low, and the constitutional unit derived from a monomer other than an olefin is more preferably not included. For example, the content of the constitutional unit derived from a monomer other than the olefin is preferably 0% by mass to 40% by mass and more preferably 0% by mass to 5% by mass with respect to the total mass of the polyolefin.

In addition, the polyolefin is preferably substantially free of a reactive group which will be described below, and a content of the constitutional unit having the reactive group is preferably 0% by mass to 3% by mass with respect to the total mass of the polyolefin.

Among these, from the viewpoint of low transmission loss, the polyolefin is preferably polyethylene, a cycloolefin polymer (COP), or a cycloolefin copolymer (COC), more preferably polyethylene, and still more preferably low-density polyethylene (LDPE).

From the viewpoint of heat resistance and moldability, the content of the polyolefin is preferably 5% by mass to 30% by mass and more preferably 10% by mass to 20% by mass with respect to the total mass of the layer A.

### —Compatible Component—

In a case where the layer A further includes a polyolefin in addition to the liquid crystal polymer, it is preferable to further include a compatible component.

Examples of the compatible component include a polymer (non-reactive compatibilizer) having a moiety having high compatibility or affinity with the liquid crystal polymer and a polymer (reactive compatibilizer) having a reactive group for a phenol-based hydroxyl group or a carboxy group at the terminal of the liquid crystal polymer.

As the reactive group included in the reactive compatibilizer, an epoxy group or a maleic anhydride group is preferable.

As the compatible component, a polymer having a portion having a high compatibility or a high affinity with the polyolefin is preferable. In addition, in a case where the layer A includes a polyolefin and a compatible component, a reactive compatibilizer is preferable as the compatible component from the viewpoint that the polyolefin can be finely dispersed.

Furthermore, the compatible component (in particular, the reactive compatibilizer) may form a chemical bond with a component such as a liquid crystal polymer in the layer A.

Examples of the reactive compatibilizer include an epoxy group-containing polyolefin-based copolymer, an epoxy group-containing vinyl-based copolymer, a maleic acid anhydride-containing polyolefin-based copolymer, a maleic acid anhydride-containing vinyl copolymer, an oxazoline group-containing polyolefin-based copolymer, an oxazoline group-containing vinyl-based copolymer, and a carboxy group-containing olefin-based copolymer. Among these, the reactive compatibilizer is preferably an epoxy group-containing polyolefin-based copolymer or a maleic acid anhydride-grafted polyolefin-based copolymer.

Examples of the epoxy group-containing polyolefin-based copolymer include an ethylene/glycidyl methacrylate copolymer, an ethylene/glycidyl methacrylate/vinyl acetate copolymer, an ethylene/glycidyl methacrylate/methyl acrylate copolymer, a polystyrene graft copolymer to an ethylene/glycidyl methacrylate copolymer (EGMA-g-PS), a polymethylmethacrylate graft copolymer to an ethylene/glycidyl methacrylate copolymer (EGMA-g-PMMA), and an acrylonitrile/styrene graft copolymer to an ethylene/glycidyl methacrylate copolymer (EGMA-g-AS).

Examples of a commercially available product of the epoxy group-containing polyolefin-based copolymer include Bondfast 2C and Bondfast E manufactured by Sumitomo Chemical Company; Lotadar manufactured by Arkema S.A.; and Modiper A4100 and Modiper A4400 manufactured by NOF Corporation.

Examples of the epoxy group-containing vinyl-based copolymer include a glycidyl methacrylate grafted polystyrene (PS-g-GMA), a glycidyl methacrylate grafted polymethyl methacrylate (PMMA-g-GMA), and a glycidyl methacrylate grafted polyacrylonitrile (PAN-g-GMA).

Examples of the maleic anhydride-containing polyolefin-based copolymer include a maleic anhydride grafted polypropylene (PP-g-MAH), a maleic anhydride grafted ethylene/propylene rubber (EPR-g-MAH), and a maleic anhydride grafted ethylene/propylene/diene rubber (EPDM-g-MAH).

Examples of a commercially available product of the maleic anhydride-containing polyolefin-based copolymer include Orevac G series manufactured by Arkema S.A.; and FUSABOND E series manufactured by The Dow Chemical Company.

Examples of the maleic anhydride-containing vinyl copolymer include a maleic anhydride grafted polystyrene (PS-g-MAH), a maleic anhydride grafted styrene/butadiene/styrene copolymer (SBS-g-MAH), a maleic anhydride grafted styrene/ethylene/butene/styrene copolymer (SEBS-g-MAH and a styrene/maleic anhydride copolymer, and an acrylic acid ester/maleic anhydride copolymer.

Examples of a commercially available product of the maleic anhydride-containing vinyl copolymer include TUFTEC M Series (SEBS-g-MAH) manufactured by Asahi Kasei Corporation.

In addition to the above description, examples of the compatible component include oxazoline-based compatibilizers (for example, a bisoxazoline-styrene-maleic anhydride copolymer, a bisoxazoline-maleic anhydride-modified polyethylene, and a bisoxazoline-maleic anhydride-modified polypropylene), elastomer-based compatibilizers (for example, an aromatic resin and a petroleum resin), and ethylene glycidyl methacrylate copolymer, an ethylene maleic anhydride ethyl acrylate copolymer, ethylene glycidyl methacrylate-acrylonitrile styrene, acid-modified polyethylene wax, a COOH-modified polyethylene graft polymer, a COOH-modified polypropylene graft polymer, a polyethylene-polyamide graft copolymer, a polypropylene-polyamide graft copolymer, a methyl methacrylate-butadiene-styrene copolymer, acrylonitrile-butadiene rubber, an EVA-PVC-graft copolymer, a vinyl acetate-ethylene copolymer, an ethylene-α-olefin copolymer, a propylene-α-olefin copolymer, a hydrogenated styrene-isopropylene-block copolymer, and an amine-modified styrene-ethylene-butene-styrene copolymer.

In addition, the compatible component may be an ionomer resin.

Examples of such an ionomer resin include an ethylene-methacrylic acid copolymer ionomer, an ethylene-acrylic acid copolymer ionomer, a propylene-methacrylic acid copolymer ionomer, a butylene-acrylic acid copolymer ionomer, a propylene-acrylic acid copolymer ionomer, an ethylene-vinyl sulfonic acid copolymer ionomer, a styrene-methacrylic acid copolymer ionomer, a sulfonated polystyrene ionomer, a fluorine-based ionomer, a telechelic polybutadiene acrylic acid ionomer, a sulfated ethylene-propylene-diene copolymer ionomer, hydrogenated polypentamer ionomer, a polypentamer ionomer, a poly(vinyl pyridinium salt) ionomer, a poly(vinyltrimethylammonium salt) ionomer, a poly(vinyl benzyl phosphonium salt) ionomer, a styrene-butadiene acrylic acid copolymer ionomer, a polyurethane ionomer, a sulfated styrene-2-acrylamide-2-methyl propane sulfate ionomer, am acid-amine Ionomer, an aliphatic ionene, and an aromatic ionene.

In a case where the layer A includes the compatible component, a content of the compatible component is preferably 0.05% by mass to 30% by mass, more preferably 0.1% by mass to 20% by mass, and still more preferably 0.5% by mass to 10% by mass with respect to the total mass of the layer A.

### —Heat Stabilizer—

From the viewpoint of suppressing thermal oxidative deterioration during melt extrusion film formation, the layer A preferably contains at least one thermal stabilizer.

Examples of the heat stabilizer include a phenol-based stabilizer and an amine-based stabilizer, each having a radical scavenging action; a phosphite-based stabilizer and a sulfur-based stabilizer, each having a decomposition action of a peroxide; and a hybrid stabilizer having a radical scavenging action and a decomposition action of a peroxide.

Examples of the phenol-based stabilizer include a hindered phenol-based stabilizer, a semi-hindered phenol-based stabilizer, and a less hindered phenol-based stabilizer.

Examples of a commercially available product of the hindered phenol-based stabilizer include ADK STAB AO-20, AO-50, AO-60, and AO-330 manufactured by ADEKA Corporation; and Irganox 259, 1035, and 1098 manufactured by BASF.

Examples of a commercially available product of the semi-hindered phenol-based stabilizer include ADK STAB AO-80 manufactured by ADEKA Corporation; and Irganox 245 manufactured by BASF.

Examples of a commercially available product of the less hindered phenol-based stabilizer include NOCRAC 300 manufactured by Ouchi Shinko Chemical Industrial Co., Ltd.; and ADK STAB AO-30 and AO-40 manufactured by ADEKA Corporation.

Examples of a commercially available product of the phosphite-based stabilizer include ADK STAB-2112, PEP-8, PEP-36, and HP-10 manufactured by ADEKA Corporation.

Examples of a commercially available product of the hybrid stabilizer include SUMILIZER GP manufactured by Sumitomo Chemical Company.

In a case where the layer A includes the heat stabilizer, a content of the heat stabilizer is preferably 0.0001% by mass to 10% by mass, more preferably 0.001% by mass to 5% by mass, and still more preferably 0.01% by mass to 2% by mass with respect to the total mass of the layer A.

### —Other Additives—

The layer A may contain an additive other than the above-described components.

Known additives can be used as other additives. Specific examples of the other additives include a curing agent, a leveling agent, an antifoaming agent, an antioxidant, an ultraviolet absorbing agent, a flame retardant, and a colorant.

From the viewpoints of the dielectric loss tangent of the film and the adhesiveness to the metal, the average thickness of the layer A is preferably thicker than the average thickness of the layer B.

From the viewpoint of dielectric loss tangent of the film and adhesiveness to the metal, a value of T^{A}/T^{B}, which is a ratio of the average thickness T^{A} of the layer A to the average thickness T^{B} of the layer B, is preferably 0.8 to 10, more preferably 1 to 5, still more preferably more than 1 and 3 or less, and particularly preferably more than 1 and 2 or less.

In addition, the average thickness of the layer A is not particularly limited, but from the viewpoint of dielectric loss tangent of the film and adhesiveness to the metal layer, the average thickness thereof is preferably 5 μm to 90 μm, more preferably 10 μm to 70 μm, and particularly preferably 15 μm to 60 μm.

A method of measuring the average thickness of each layer in the film according to the embodiment of the present disclosure is as follows.

The thickness of each layer is evaluated by cutting the film with a microtome and observing the cross section with an optical microscope. Three or more sites of the cross-sectional sample are cut out, the thickness is measured at three or more points in each cross section, and the average value thereof is defined as the average thickness.

### <Layer B>

In the film according to the embodiment of the present disclosure, the layer B is disposed on at least one surface of the layer A.

The clastic modulus EB of the layer B at 160° C. is preferably 0.1 GPa or less, more preferably 0.01 GPa or less, and still more preferably 0.002 GPa or less. In a case where the clastic modulus EB of the layer B at 160° C. is small, the layer B can be deformed along the step, and the step followability is improved. The lower limit value of the elastic modulus EB is not particularly limited, and is, for example, 0.00001 GPa.

From the viewpoint of the dielectric loss tangent of the film and the step followability, the dielectric loss tangent of the layer B is preferably 0.008 or less, more preferably 0.005 or less, still more preferably 0.002 or less, and particularly preferably 0 super to 0.001.

The components constituting the layer B are not particularly limited as long as the elastic modulus EA and the clastic modulus EB satisfy the above-described ratio. Since the layer B easily satisfies the above ratio, it is preferable that the layer B contains at least one polymer.

The type of the polymer is not particularly limited, and a known polymer can be used. Examples of the polymer include a (meth)acrylic resin, polyvinyl cinnamate, polycarbonate, polyimide, polyamideimide, polyesterimide, polyetherimide, polyether ketone, polyether ether ketone, polyethersulfone, polysulfone, poly-p-xylylene, polyester, polyvinyl acetal, polyvinyl chloride, polyvinyl acetate, polyamide, polystyrene, polyurethane, polyvinyl alcohol, cellulose acylate, a fluorinated resin, a liquid crystal polymer, syndiotactic polystyrene, a silicone resin, an epoxy silicone resin, a phenol resin, an alkyd resin, an epoxy resin, a maleic acid resin, a melamine resin, a urea resin, an aromatic sulfonamide, a benzoguanamine resin, a silicone elastomer, and a polyolefin. Among these, the polymer is preferably a polyimide or a polyolefin.

### —Cured Substance of Composition Containing Polymer and Compound Having Reactive Group—

In addition, from the viewpoint of the adhesiveness to the layer A and the adhesiveness to the metal layer, the layer B preferably includes a cured substance of a composition containing a polymer and a compound having a reactive group. Hereinafter, the compound having a reactive group will also be referred to as a “reactive compound”.

The reactive group contained in the reactive compound is preferably a group capable of reacting with a group that may exist on a surface of the layer A (in particular, a group having an oxygen atom, such as a carboxy group and a hydroxy group). In addition, the reactive group contained in the reactive compound is preferably a group capable of reacting with a metal surface.

Examples of the reactive group include an epoxy group, an oxetanyl group, an isocyanate group, an acid anhydride group, a carbodiimide group, an N-hydroxyester group, a glyoxal group, an imide ester group, a halogenated alkyl group, and a thiol group.

Among these, the reactive group is preferably at least one group selected from the group consisting of an epoxy group, an acid anhydride group, and a carbodiimide group, and more preferably an epoxy group.

Examples of the compound having an epoxy group include aromatic glycidylamine (for example, N,N-diglycidyl-4-glycidyloxyaniline, 4,4′-methylenebis(N,N-diglycidylaniline), N,N-diglycidyl-o-toluidine, and N,N,N′,N′-tetraglycidyl-m-xylene diamine, 4-t-butylphenylglycidyl ether), aliphatic glycidylamine (for example, 1,3-bis(diglycidylaminomethyl) cyclohexane), and aliphatic glycidyl ether (for example, sorbitol polyglycidyl ether). Among these, as the compound having an epoxy group, an aromatic glycidylamine compound is preferable from the viewpoint of improving the adhesiveness to the metal layer.

Examples of the compound having an acid anhydride group include tetracarboxylic dianhydrides (for example, 3,3′,4,4′-benzophenone tetracarboxylic dianhydride, 3,3′,4,4′-biphenyltetracarboxylic dianhydride, pyromellitic dianhydride, 2,3,3′,4′-biphenyltetracarboxylic dianhydride, oxydiphthalic dianhydride, diphenylsulfone-3,4,3′,4′-tetracarboxylic dianhydride, bis(3,4-dicarboxyphenyl) sulfide dianhydride, 2,2-bis(3,4-dicarboxyphenyl)-1,1,1,3,3,3-hexafluoropropane dianhydride, 2,3,3′,4′-benzophenone tetracarboxylic dianhydride, bis(3,4-dicarboxyphenyl) methane dianhydride, 2,2-bis(3,4-dicarboxyphenyl) propane dianhydride, p-phenylenebis(trimellitic acid monoester anhydride), p-biphenylenebis(trimellitic acid monoester anhydride), m-terphenyl-3,4,3′,4′-tetracarboxylic dianhydride, p-terphenyl-3,4,3′,4′-tetracarboxylic dianhydride, 1,3-bis(3,4-dicarboxyphenoxy)benzene dianhydride, 1,4-bis(3,4-dicarboxyphenoxy)benzene dianhydride, 1,4-bis(3,4-dicarboxyphenoxy) biphenyl dianhydride, 2,2-bis [(3,4-dicarboxyphenoxy)phenyl]propane dianhydride, 2,3,6,7-naphthalenetetracarboxylic dianhydride, 1,4,5,8-naphthalenetetracarboxylic dianhydride, and 4,4′-(2,2-hexafluoroisopropyridene)diphthalic dianhydride).

Examples of the compound having a carbodiimide group include monocarbodiimide compounds (for example, dicyclohexylcarbodiimide, diisopropylcarbodiimide, dimethylcarbodiimide, diisobutylcarbodiimide, dioctylcarbodiimide, t-butylisopropylcarbodiimide, diphenylcarbodiimide, di-t-butylcarbodiimide, di-β-naphthylcarbodiimide, N,N′-di-2,6-diisopropylphenylcarbodiimide), and polycarbodiimide compounds (for example, the compounds described in U.S. Pat. No. 2,941,956A, JP1972-033279B (JP-S47-033279B), J. Org. Chem. 28, p. 2069-2075 (1963), Chemical Review 1981, 81, No. 4, p. 619-621, and the like).

Examples of a commercially available product of the reactive compound having a carbodiimide group include Carbodilite (registered trademark) HMV-8CA, LA-1, and V-03 (both manufactured by Nisshinbo Chemical Inc.), and Stabaxol (registered trademark) P, P100, and P400 (all manufactured by Rhein Chemie Japan Ltd.), and Stabilizer 9000 (trade name, manufactured by Rhein Chemie Corporation).

The number of the reactive groups contained in the reactive compound is 1 or more, but is preferably 3 or more from the viewpoint that the adhesiveness to the metal layer is more excellent.

From the viewpoint of the adhesion strength and the film hardness, the number of reactive groups contained in the reactive compound is preferably 6 or less, more preferably 5 or less, and still more preferably 4 or less.

The reactive compounds may be used alone or in combination of two or more kinds thereof.

Among these, the cured substance of a composition containing a polymer and a compound having a reactive group is preferably a cured substance of a composition containing the polyimide and the epoxy compound or a cured substance of a composition containing the polyolefin and the epoxy compound.

The polyimide is not particularly limited as long as it is a polymer including an imide bond.

Examples of the polyolefin include the same polyolefin as the polyolefin that can be contained in the layer A.

From the viewpoint of low transmission loss, the polyolefin is preferably polyethylene, a cycloolefin polymer (COP), a cycloolefin copolymer (COC), or a styrene-ethylene/butylene-styrene copolymer (SEBS), and more preferably polyethylene or SEBS.

### —Filler—

The layer B may contain at least one filler from the viewpoint of the thermal expansion coefficient and the adhesiveness to the metal layer.

The filler may be particulate or fibrous. The filler may be an inorganic filler or an organic filler. From the viewpoint of the dielectric loss tangent and the step followability of the film, the filler is preferably an organic filler.

As the organic filler, a known organic filler can be used.

Examples of a material of the organic filler include polyethylene, polystyrene, urea-formalin filler, polyester, cellulose, acrylic resin, fluororesin, cured epoxy resin, crosslinked benzoguanamine resin, crosslinked acrylic resin, a liquid crystal polymer, and a material containing two or more kinds of these.

In addition, the organic filler may be fibrous, such as nanofibers, or may be hollow resin particles.

Among these, from the viewpoint of the dielectric loss tangent of the film and the level difference followability, the organic filler is particularly preferably fluororesin particles, polyester-based resin particles, polyethylene particles, liquid crystal polymer particles, or cellulose-based resin nanofibers are preferable, polytetrafluoroethylene particles, polyethylene particles, or liquid crystal polymer particles are more preferable, and liquid crystal polymer particles. Here, the liquid crystal polymer particles are not limited, but refer to particles obtained by polymerizing a liquid crystal polymer and crushing the liquid crystal polymer with a crusher or the like to obtain powdery liquid crystal. The liquid crystal polymer particles are preferably smaller than the thickness of each layer.

From the viewpoints of the dielectric loss tangent of the film, the laser processing suitability, and the level difference followability, the average particle diameter of the organic filler is preferably 5 nm to 20 μm and more preferably 100 nm to 10 μm.

As the inorganic filler, a known inorganic filler can be used.

Examples of a material of the inorganic filler include BN, Al₂O₃, AlN, TiO₂, SiO₂, barium titanate, strontium titanate, aluminum hydroxide, calcium carbonate, and a material containing two or more of these.

Among these, from the viewpoint of thermal expansion coefficient and adhesiveness with the metal layer, the inorganic filler is preferably metal oxide particles or fibers, more preferably silica particles, titania particles, or glass fibers, and is particularly preferably silica particles or glass fibers.

An average particle diameter of the inorganic filler is preferably approximately 20% to approximately 40% of the thickness of a layer A, and for example, the average particle diameter may be selected from 25%, 30%, or 35% of the thickness of the layer A. In a case where the particles or fibers are flat, the average particle diameter indicates a length in a short side direction.

In addition, from the viewpoint of thermal expansion coefficient and adhesiveness with the metal layer, the average particle diameter of the inorganic filler is preferably 5 nm to 20 μm, more preferably 10 nm to 10 μm, still more preferably 20 nm to 1 μm, and particularly preferably 25 nm to 500 nm.

### —Other Additives—

The layer B may contain an additive other than the above-described components.

Known additives can be used as other additives. Specific examples of the other additives include a curing agent, a leveling agent, an antifoaming agent, an antioxidant, an ultraviolet absorbing agent, a flame retardant, and a colorant.

The average thickness of the layer B is not particularly limited, but from the viewpoint of step followability, is preferably 15 μm or less, more preferably 10 μm or less, and particularly preferably 5 μm or less. The lower limit value of the average thickness of the layer B is not particularly limited, and is, for example, 1 μm.

It is preferable that the layer B is a surface layer (outermost layer) of the film. The layer configuration of the film is preferably a layer A/layer B or a layer B/layer A/layer B.

### <Layer C>

It is preferable that the film according to the embodiment of the present disclosure further includes a layer C, in which the layer C, the layer A, and the layer B are arranged in this order.

The layer C is a layer different from the layer A in terms of composition and physical properties. The layer C may be the same as or different from the layer B in terms of composition and physical properties. The fact that the composition of the layer C is the same as that of the layer A or the layer B means that the types and the contents of the components contained in the layers are the same.

The layer C preferably contains at least one polymer.

The type of the polymer is not particularly limited, and a known polymer can be used.

From the viewpoint of the adhesiveness to the layer A and the adhesiveness to the metal layer, the layer C preferably includes a cured substance of a composition including a polymer and a reactive compound. The preferred aspect of the cured substance of the composition including the polymer and the reactive compound is the same as the preferred aspect of the cured substance of the composition including the polymer and the reactive compound in the layer B.

The layer C may contain at least one filler from the viewpoint of the thermal expansion coefficient and the adhesiveness to the metal layer.

Examples of the filler which may be contained in the layer C include the same ones as the filler which may be contained in the layer B.

The layer C may contain an additive other than the above-described components.

Known additives can be used as other additives. Specific examples of the other additives include a curing agent, a leveling agent, an antifoaming agent, an antioxidant, an ultraviolet absorbing agent, a flame retardant, and a colorant.

From the viewpoint of dielectric loss tangent of the film and adhesiveness to the metal, it is preferable that an average thickness of the layer C is smaller than an average thickness of the layer A.

From the viewpoint of dielectric loss tangent of the film and adhesiveness to the metal layer, a value of T^{A}/T^{C}, which is a ratio of the average thickness T^{A} of the layer A to an average thickness T^{C} of the layer C, is preferably more than 1, more preferably 2 to 100, still more preferably 2.5 to 20, and particularly preferably 3 to 10.

The average thickness of the layer C is not particularly limited, but is preferably 15 μm or less, more preferably 10 μm or less, and particularly preferably 5 μm or less from the viewpoint of low transmission loss. The lower limit value of the average thickness of the layer C is not particularly limited, and is, for example, 1 μm.

From the viewpoint of strength and electrical characteristics (characteristic impedance) in a case of being laminated with the metal layer, an average thickness of the film according to the embodiment of the present disclosure is preferably 6 μm to 200 μm, more preferably 12 μm to 100 μm, and particularly preferably 20 μm to 80 μm.

The average thickness of the film is measured at optional five sites using an adhesive film thickness meter, for example, an electronic micrometer (product name, “KG3001A”, manufactured by Anritsu Corporation), and the average value of the measured values is defined as the average thickness of the film.

### [Manufacturing Method of Film]

A manufacturing method of a film according to the present disclosure is not particularly limited, and includes, for example, a step of forming a layer A using a composition for forming the layer A (composition for forming a layer A) and a step of forming a layer B on at least one surface of the layer A formed in the step (hereinafter, also referred to as “step B”) using a composition for forming the layer B (composition for forming a layer B).

Hereinafter, the step A and the step B will be described.

### <Step A>

The step A includes, for example, a pelletizing step of kneading a raw material (raw material for forming the layer A) for forming the layer A described above to obtain pellets and a film forming step of forming a film by using the pellets. The produced molded body is the layer A in the film.

Hereinafter, the step A will be described in detail.

### (Pelletizing Step)

### (1) Forms of Raw Materials

As the polymer used for film formation, a pellet-shaped, flake-shaped, or powder-shaped polymer may be used as it is. It is preferable to use pellets obtained by kneading one or more types of raw materials using an extruder and pelletizing the kneaded materials for the purpose of stabilizing film formation or uniformly dispersing components other than the polymer.

### (2) Drying or Drying Alternative by Vent

In a case of performing pelletization, it is preferable that the raw materials are dried in advance. As a drying method, there are a method of circulating heated air having a low dew point and a method of dehumidifying by vacuum drying. In particular, in a case of using a polymer that is easily oxidized, vacuum drying or drying using an inert gas is preferable.

### (3) Method for Supplying Raw Materials

The raw material supply method may be a method of premixing and supplying the raw materials before kneading and pelletizing, a method of separately supplying the raw materials into the extruder so that a certain ratio is obtained, or a method of combining both.

### (4) Atmosphere in Extrusion Step

In a case of performing melt extrusion, to an extent that uniform dispersion is not hindered, it is preferable to prevent thermal and oxidative deterioration as much as possible, and it is also effective to reduce an oxygen concentration by reducing a pressure using a vacuum pump or inflowing an inert gas. These methods may be carried out alone or in combination.

### (5) Temperature

The kneading temperature is preferably set to a temperature equal to or lower than a thermal decomposition temperature of the raw material, and is preferably set to a temperature as low as possible within a range where a load of the extruder and a decrease in uniform kneading property are not problematic.

### (6) Pressure

The pelleting is preferably performed at a pressure of 0.05 MPa to 30 MPa. In a case of a raw material that is likely to be colored or to generate a gel due to shearing, it is preferable to apply an internal pressure of approximately 1 MPa to 10 MPa in the extruder to fill the extruder with the raw material.

### (7) Pelletizing Method

As the pelletizing method, a method of extruding the composition into a noodle shape, solidifying the composition in water, and then cutting the composition is generally used. The composition may be pelletized by an underwater cut method of cutting the composition directly from a mouthpiece into water after melting by an extruder or a hot cut method of cutting the composition in a hot state.

### (8) Pellet Size

The pellet size is preferably a cross-sectional area of 1 mm² to 300 mm² and a length of 1 mm to 30 mm, and more preferably a cross-sectional area of 2 mm² to 100 mm² and a length of 1.5 mm to 10 mm.

### (Drying)

### (1) Purpose of Drying

Before forming a molten film, it is preferable to reduce a moisture and a volatile component in the pellets, and it is effective to dry the pellets. By reducing the moisture or the volatile component in the pellets, it is possible to suppress a decrease in appearance due to the incorporation of bubbles or a decrease in haze and to suppress a deterioration in physical properties due to the molecular chain scission of the polymer or the occurrence of roll stains due to the generation of a monomer or an oligomer. In addition, depending on a type of the polymer to be used, it can also make it possible to suppress formation of an oxidative crosslinked substance during molten film formation by removing dissolved oxygen by the drying in some cases.

### (2) Drying Method and Heating Method

In terms of drying efficiency and economy, a dehumidifying hot air dryer is generally used as a drying method, but the drying method is not particularly limited as long as it enables a desired moisture content to be obtained. In addition, the solvent can be appropriately selected according to the physical properties of the polymer.

Examples of the heating method include pressurized steam, heater heating, far-infrared irradiation, microwave heating, and a heat medium circulation heating method.

### (Film Producing Step)

Hereinafter, the film forming step will be described.

### (1) Extrusion Conditions

### Drying of Raw Materials

In the pellet melt plasticization step by the extruder, it is also preferable to reduce the moisture and the volatile components as in the pelletizing step, and it is effective to dry the pellets.

### Raw Material Supply Method

In a case where there are multiple types of raw materials (pellets) input from the extruder supply port, the raw materials may be mixed in advance (premix method), may be separately supplied into the extruder in a fixed ratio, or may be a combination of the both. In addition, in order to stabilize the extrusion, it is generally practiced to reduce a fluctuation of the temperature and a bulk specific gravity of the raw material charged from the supply port.

The temperature of the raw material may be in a range that the raw material is bonded and does not block the supply port from the viewpoint of the plasticization efficiency, and is preferably high. In a case where the polymer is in an amorphous state, it is preferable to adjust the temperature of the raw material in a range between a temperature equal to or higher than a temperature lower than the glass transition temperature by 150° C. and a temperature equal to or lower than a temperature lower than the glass transition temperature by 1° C. In addition, in a case of the crystalline resin, it is preferable to adjust the temperature of the raw material in a range between a temperature equal to or higher than the melting point and a temperature equal to or lower than the melting point by 1° C.

In addition, from the viewpoint of the plasticization efficiency, a bulk specific gravity of the raw material is preferably 0.3 times or more, and more preferably 0.4 times or more the bulk specific gravity in a case of a molten state. In a case where the bulk specific density of the raw material is less than 0.3 times the bulk specific gravity in the molten state, it is also preferable to perform a processing treatment such as compressing the raw material into pseudo-pellets.

### Atmosphere of Extrusion Step

As for the atmosphere during melt extrusion, it is necessary to prevent heat and oxidative deterioration as much as possible within a range that does not hinder uniform dispersion as in the pelletizing step. It is also effective to inject an inert gas (nitrogen or the like), reduce the oxygen concentration in the extruder by using a vacuum hopper, and provide a vent port in the extruder to reduce the pressure by a vacuum pump. These decompression and injection of the inert gas may be carried out independently or in combination.

### Rotation Speed

The rotation speed of the extruder is preferably 5 revolutions per minute (rpm) to 300 rpm, more preferably 10 rpm to 200 rpm, and still more preferably 15 rpm to 100 rpm. In a case where the rotation rate is set to the lower limit value or more, the retention time is shortened, the decrease in the molecular weight can be suppressed due to thermal deterioration, and discoloration can be suppressed. In a case where the rotation rate is set to the upper limit value or less, a breakage of a molecular chain due to shearing can be suppressed, and a decrease in molecular weight and an increase in generation of crosslinked gel can be suppressed. For the rotation speed, it is preferable to select appropriate conditions from the viewpoints of both uniform dispersibility and thermal deterioration due to extension of the retention time.

### Temperature

A barrel temperature (a supply unit temperature of T1° C., a compression unit temperature of T2° C., and a measuring unit temperature of T3° C.) is generally determined by the following method. In a case where the pellets are melt-plasticized at a target temperature T° C. by the extruder, the measuring unit temperature T3 is set to T±20° C. in consideration of the shear calorific value. At this time, T2 is set within the range of T3±20° C. in consideration of the extrusion stability and the thermal decomposability of the raw material. T1 is generally set to be in a range between a temperature equal to or higher than a temperature lower than T2 by 150° C. and a temperature equal to or lower than a temperature lower than T2 by 5° C., and an optimal value is selected based on achieving both sufficient friction between the raw material and the barrel, which serves as a driving force (feed force) for feeding the raw material, and preheating in the feed portion. In a case of a normal extruder, it is possible to subdivide each zone of T1 to T3 and set the temperature, and by performing settings such that the temperature change between each zone is gentle, it is possible to make it more stable. At this time, Tis preferably set to be equal to or lower than the thermal deterioration temperature of the raw material, and in a case where it exceeds the thermal deterioration temperature due to the shear heat generation of the extruder, it is generally performed to positively cool and remove the shear heat generation. In addition, in order to achieve both the improved dispersibility and the thermal deterioration, it is also effective to melt and mix a first half part in the extruder at a relatively high temperature and lower the temperature of the raw material in a second half part.

### Pressure

The pressure in the extruder is generally 1 MPa to 50 MPa, and is preferably 2 MPa to 30 MPa and more preferably 3 MPa to 20 MPa in terms of extrusion stability and melt uniformity. In a case where the pressure in the extruder is 1 MPa or more, a filling rate of the melting in the extruder is sufficient, and therefore, the destabilization of the extrusion pressure and the generation of foreign matter due to the generation of retention portions can be suppressed. In addition, in a case where the pressure in the extruder is 50 MPa or less, it is possible to suppress the excessive shear stress received in the extruder, and therefore, thermal decomposition due to an increase in the temperature of the raw material can be suppressed.

### Retention Time

A retention time in the extruder (retention time during the film formation) can be calculated from a volume of the extruder portion and a discharge capacity of the polymer, as in the pelletizing step. The retention time is preferably 10 seconds to 60 minutes, more preferably 15 seconds to 45 minutes, and still more preferably 30 seconds to 30 minutes. In a case where the retention time is 10 seconds or longer, the melt plasticization and the dispersion of the other components are sufficient. In a case where the retention time is 30 minutes or less, the deterioration of the polymer and the discoloration of the polymer can be suppressed, which is preferable.

### (Filtration)

### Type, Purpose of Installation, and Structure

It is generally used to provide a filtration equipment at the outlet of the extruder in order to prevent damage to the gear pump due to foreign matter included in the raw material and to extend the life of the filter having a fine pore size installed downstream of the extruder. It is preferable to perform so-called breaker plate type filtration in which a mesh-shaped filtering medium is used in combination with a reinforcing plate having a high opening ratio and having strength.

### Mesh Size and Filtration Area

A mesh size is preferably 40 mesh to 800 mesh, more preferably 60 mesh to 700 mesh, and still more preferably 100 mesh to 600 mesh. In a case where the mesh size is 40 mesh or more, it is possible to sufficiently suppress foreign matter from passing through the mesh. Furthermore, in a case where the mesh is 800 mesh or less, the improvement of the filtration pressure increase speed can be suppressed and the mesh replacement frequency can be reduced. Moreover, in terms of filtration accuracy and strength maintenance, a plurality of types of filter meshes having different mesh sizes are often superimposed and used. In addition, since the filtration opening area can be widened and the strength of the mesh can be maintained, the filter mesh may also be reinforced by using a breaker plate. An opening ratio of the breaker plate used is often 30% to 80% in terms of filtration efficiency and strength.

In addition, a screen changer with the same diameter as the barrel diameter of the extruder is often used, but in order to increase the filtration area, a larger diameter filter mesh is used by using a tapered pipe, or a plurality of breaker plates is also sometimes used by branching a flow channel. A filtration area is preferably selected with a flow rate of 0.05 g/cm² to 5 g/cm² per second as a guide, more preferably 0.1 g/cm² to 3 g/cm², and still more preferably 0.2 g/cm² to 2 g/cm².

By capturing foreign matter, the filter is clogged and the filter pressure rises. At that time, it is necessary to stop the extruder and replace the filter, but a type in which the filter can be replaced while continuing extrusion can also be used. In addition, as a measure against an increase in the filtration pressure due to the capture of foreign matter, a measure having a function of lowering the filtration pressure by cleaning and removing the foreign matter trapped in the filter by reversing the flow channel of the polymer can also be used.

### (Die)

### Type, Structure, and Material

The raw material from which the foreign matter has been removed by filtration and the temperature has been made uniform by the mixer is continuously fed to the die. The die is not particularly limited as long as it is designed so that the retention of the raw material is small, and any type of a T die, a fishtail die, or a hanger coat die, which is commonly used, can also be used. Among these, as the die, a hanger-coat die is preferable from the viewpoint of thickness uniformity and less retention.

### Multilayer Film Formation

For the film formation, for example, a single-layer film forming apparatus having a low equipment cost is used. In addition, a multilayer film forming apparatus may be used to manufacture a film having a functional layer such as a layer B, a surface protective layer, a pressure-sensitive adhesive layer, an easy adhesion layer, and/or an antistatic layer. Specific examples thereof include a method of performing multilayering using a multilayer feed block and a method of using a multi-manifold die. It is preferable to laminate the functional layer thinly on the surface layer, but the layer ratio is not particularly limited.

### Cast

The film forming step preferably includes a step of supplying a raw material in a molten state from the supply unit and a step of landing the raw material in the molten state on a cast roll to form a film. The molded body may be cooled and solidified and then wound as it is, or may be continuously compressed and passed between a pair of compression surfaces to be molded into a film shape.

A unit for supplying the raw material (melt) in a molten state is not particularly limited. For example, as a specific supplying unit of the melt, an extruder that melts a raw material and extrudes the raw material into a film may be used, an extruder and a die may be used, or a method in which the raw material is once solidified into a film shape, then melted by a heating unit to form a melt, and then supplied to the film forming step may be used.

In a case where the molten resin extruded from the die in a sheet shape is sandwich-pressed by a device having a pair of sandwiching surfaces, the surface morphology of the sandwiching surfaces can be transferred to the surface of the molded body. In addition, in a case where the raw material contains a liquid crystal polymer, the aligning properties can be controlled by imparting a stretching deformation.

### Film Forming Method and Type

Among the methods of molding a raw material in a molten state into a film shape, it is preferable to pass the raw material between two rolls (for example, a touch roll and a chill roll) from the viewpoint that a high pressing pressure can be applied and the surface shape of the molded body is excellent. Furthermore, in the present specification, in a case where a plurality of cast rolls for transporting a molten substance are provided, the cast roll closest to the most upstream supply unit (for example, a die) is referred to as a chill roll. Additionally, a method of pressurizing metal belts with each other or a method of combining a roll and a metal belt can also be used. In addition, in some cases, in order to improve the adhesiveness with the roll or the metal belt, a film forming method such as a static electricity application method, an air knife method, an air chamber method, and a vacuum nozzle method can be used in combination, on a cast drum.

In addition, in a case of obtaining a molded body having a multilayer structure, it is preferable to obtain the molded body by interposing the raw material extruded from the die in a multilayer manner, but it is also possible to obtain a molded body having a multilayer structure by introducing a molded body having a monolayer structure into a clamped portion in a manner of melt lamination. In addition, by changing the circumferential speed difference or the alignment axis direction of the clamped portion, a molded body having an inclined structure in the thickness direction can be obtained, and by performing this step several times, a molded body having three or more layers can be obtained.

Furthermore, the touch roll may be periodically vibrated in the TD direction in a case of pressurizing to give deformation.

### Temperature of Molten Raw Material

The jetting temperature (temperature of the raw material at the exit of the supply unit) is a temperature that is 10° C. or lower than the melting point of the raw material and is preferably in a range of a temperature that is 40° C. or higher than the melting point of the raw material. The melt viscosity is preferably 50 Pa·s to 3500 Pa·s.

It is preferable that the temperature change due to the cooling of the molten raw material between the air gaps is as small as possible. It is preferable to make the temperature decrease by cooling small by making various contrivances such as increasing the film forming speed and shortening the air gap.

### Temperature of Touch Roll

The temperature of the touch roll is preferably set to a glass transition temperature (Tg) or lower of the raw material. In a case where the temperature of the touch roll is Tg or lower of the polymer, since pressure-sensitive adhesion of the raw material to the roll can be suppressed, the appearance of the molded body is improved. For similar reasons, it is preferable to set the chill roll temperature to be Tg of the raw material or lower.

### Film Formation Procedure

In the film forming step, it is preferable to perform the film forming by landing the molten raw material discharged from the die on a cast roll to form a film, cooling and solidifying the film, and winding the film in terms of stabilization of the film forming step and the quality.

In a case of performing the sandwiching and pressing of the molten raw material, the molten raw material is passed through between the first sandwiching and pressing surface and the second sandwiching and pressing surface set at a predetermined temperature, and the molten raw material is cooled and solidified, and then wound.

### (Stretching Step, Thermal Relaxation Treatment, and Thermal Fixation Treatment)

Further, after obtaining the unstretched molded body by the above method, the molded body may be stretched continuously or discontinuously and/or subjected to a thermal relaxation treatment or a thermal fixation treatment. For example, each step can be carried out by the combination of the following (a) to (g). In addition, the order of the machine-direction stretching and the cross-direction stretching may be reversed, each step of the machine-direction stretching and the cross-direction stretching may be performed in multiple stages, and each step of the machine-direction stretching and the cross-direction stretching may be combined with diagonal stretching or simultaneous biaxial stretching.
(a) Cross-direction stretching
(b) Cross-direction stretching→Thermal relaxation treatment
(c) Machine-direction stretching
(d) Machine-direction stretching→Thermal relaxation treatment
(e) Machine-direction (cross-direction) stretching→Cross-direction (machine-direction) stretching
(f) Machine-direction (cross-direction) stretching Cross→direction (machine-direction) stretching→Thermal relaxation treatment
(g) Cross-direction stretching→Thermal relaxation treatment→Machine-direction stretching→Thermal relaxation treatment

### Machine-Direction Stretching

The machine-direction stretching can be achieved by making the circumferential speed on the outlet side faster than the circumferential speed on the inlet side while heating between the two pairs of rolls. From the viewpoint of suppressing curling, it is preferable that the front and back surfaces of the molded body to be stretched are at the same temperature, but in a case where the optical properties are controlled in the thickness direction, stretching can be performed at different temperatures of the front and back surfaces. The stretching temperature here is defined as a temperature on a lower side of the surface of the molded body. The machine-direction stretching step may be carried out in either one step or multiple steps. Preheating of the unstretched molded body is often performed by passing through a temperature-controlled heating roll, but in some cases, heating can be performed using a heater. In addition, in order to prevent the adhesion to the roll of the molded body on which the stretching treatment is performed, a ceramic roll or the like having improved pressure-sensitive adhesiveness can also be used.

### Cross-Direction Stretching

As the cross-direction stretching step, normal cross-direction stretching can be adopted. That is, examples of the normal cross-direction stretching include a stretching method in which both ends in the width direction of the molded body to be subjected to a stretching treatment are gripped with clips, and the clips are widened while being heated in an oven using a tenter. With regard to the cross-direction stretching step, for example, methods described in JP1987-035817U (JP-S62-035817U), JP2001-138394A, JP1998-249934A (JP-H10-249934A), JP1994-270246A (JP-H06-270246A), JP1992-030922U (JP-H04-030922U), and JP1987-152721A (JP-S62-152721A) can be used, and these methods are herein incorporated by reference.

The stretching ratio (cross-direction stretching ratio) of the molded body in the width direction in the cross-direction stretching step is preferably 1.2 times to 6 times, more preferably 1.5 times to 5 times, and still more preferably 2 times to 4 times. In addition, the cross-direction stretching ratio is preferably larger than the stretching ratio of the machine-direction stretching in a case where the machine-direction stretching is performed.

The stretching temperature in the cross-direction stretching step can be controlled by blowing air at a desired temperature into the tenter. The film temperatures may be the same or different on the front and back surfaces for the same reason as in the machine-direction stretching. The stretching temperature used herein is defined as a temperature on a lower side of the surface of the molded body. The cross-direction stretching step may be carried out in one step or in multiple steps. In addition, in a case of performing cross-direction stretching in multiple stages, the cross-direction stretching may be performed continuously or intermittently by providing a zone in which widening is not performed. For such the cross-direction stretching, in addition to the normal cross-direction stretching in which a clip is widened in the width direction in a tenter, a stretching method as below, in which a clip is widened by gripping, can also be applied.

### Diagonal Stretching

In the diagonal stretching step, the clips are widened in the cross-direction in the same manner as in the normal cross-direction stretching, but can be stretched diagonally by changing a transportation speed of the left and right clips. As the diagonal stretching step, for example, the methods described in JP2002-022944A, JP2002-086554A, JP2004-325561A, JP2008-023775A, and JP2008-110573A can be used.

### Simultaneous Biaxial Stretching

The simultaneous biaxial stretching is a treatment in which clips are widened in the cross-direction, and simultaneously stretched or shrunk in the machine direction, in a similar manner to the normal cross-direction stretching. As the simultaneous biaxial stretching, for example, the methods described in JP1980-093520U (JP-S55-093520U), JP1988-247021A (JP-S63-247021A), JP1994-210726A (JP-H06-210726A), JP1994-278204A (JP-H06-278204A), JP2000-334832A, JP2004-106434A, JP2004-195712A, JP2006-142595A, JP2007-210306A, JP2005-022087A, JP2006-517608A, and JP2007-210306A can be used.

### Heat Treatment to Improve Bowing (Axis Misalignment)

Since the end part of the molded body is gripped by the clip in the above-described cross-direction stretching step, the deformation of the molded body due to the thermal shrinkage stress generated during the heat treatment is large in a central portion of the molded body and is small in the end part, and as a result, the distribution of the characteristics in the width direction can be performed. In a case where a straight line is drawn along the lateral direction on the surface of the molded body before the heat treatment step, the straight line on the surface of the molded body after the heat treatment step is a bow shape in which the center portion is recessed toward the downstream side. This phenomenon is called a bowing phenomenon, and causes a deterioration in the isotropy and the uniformity in the width direction of the molded body.

With an improvement method therefor, it is possible to reduce a variation in an alignment angle due to the bowing by performing preheating before the cross-direction stretching or by performing the thermal fixation after the stretching. Any one of the preheating or the thermal fixation may be performed, but it is more preferable to perform the both. It is preferable to perform the preheating and the thermal fixation by gripping with a clip, that is, it is preferable to perform the preheating and the thermal fixation continuously with the stretching.

The preheating temperature is preferably higher than the stretching temperature by about 1° C. to 50° C., more preferably higher than the stretching temperature by 2° C. to 40° C., and still more preferably higher than the stretching temperature by 3° C. to 30° C. The preheating time is preferably 1 second to 10 minutes, more preferably 5 seconds to 4 minutes, and still more preferably 10 seconds to 2 minutes.

During the preheating, it is preferable to keep the width of the tenter almost constant. The term “almost” as mentioned herein refers to +10% of the width of the unstretched film.

The heat fixation temperature is preferably 1° C. to 50° C. lower than the stretching temperature, more preferably 2° C. to 40° C. lower than the stretching temperature, and still more preferably 3° C. to 30° C. lower than the stretching temperature. The thermal fixation temperature is preferably a temperature that is equal to or lower than the stretching temperature and equal to or lower than the Tg of the liquid crystal polymer.

The thermal fixation time is preferably 1 second to 10 minutes, more preferably 5 seconds to 4 minutes, and still more preferably 10 seconds to 2 minutes. In a case of the thermal fixation, it is preferable to keep the width of the tenter almost constant. The term “almost” as mentioned herein means 0% (the same width as the tenter width after stretching) to −30% (30% smaller than the tenter width after stretching=reduced width) of the tenter width after the completion of stretching. Examples of other known methods include the methods described in JP1989-165423A (JP-H01-165423A), JP1991-216326A (JP-H03-216326A), JP2002-018948A, and JP2002-137286A.

### Thermal Relaxation Treatment

After the stretching step, a thermal relaxation treatment of heating the molded body to shrink the molded body may be performed. By performing the thermal relaxation treatment, the thermal shrinkage rate of the film can be reduced. It is preferable that the thermal relaxation treatment is carried out at at least one timing of a time after film formation, a time after machine-direction stretching, or a time after cross-direction stretching.

The thermal relaxation treatment may be continuously performed online after the stretching, or may be performed offline after winding after the stretching. Examples of the temperature of the thermal relaxation treatment include a glass transition temperature Tg or higher and a melting point Tm or lower of the raw material. In a case where there is a concern about oxidative deterioration of the polymer, the thermal relaxation treatment may be performed in an inert gas such as a nitrogen gas, an argon gas, and a helium gas.

### (Annealing Treatment)

In the step A, from the viewpoint of further improving the electrical characteristics, it is preferable to perform an annealing treatment of heating the molded body after stretching the molded body.

In the annealing treatment, when the melting point of the raw material is set to Tm (° C.), the heating temperature is preferably equal to or higher than a temperature lower than the melting point by 200° C., more preferably equal to or higher than a temperature lower than the melting point by 100° C., and still more preferably a temperature equal to or higher than the melting point by 50° C. The upper limit of the heating temperature in the annealing treatment is preferably a temperature equal to or lower than a temperature higher than the melting point by 50° C., and more preferably a temperature equal to or lower than a temperature higher than the melting point by 30° C.

In addition, the heating temperature in the annealing treatment is preferably 240° C. or higher, more preferably 255° C. or higher, and still more preferably 270° C. or higher. In addition, the heating temperature in the annealing treatment is preferably 370° C. or lower and more preferably 350° C. or lower.

Examples of a heating unit used for the annealing treatment include a hot air drying furnace and an infrared heater, and from the viewpoint that a film having a desired melting peak area can be produced in a short time, the infrared heater is preferable. In addition, as the heating unit, pressurized steam, microwave heating, and a heat medium circulation heating method may be used.

The treatment time of the annealing treatment can be appropriately adjusted depending on the type of the raw material, the heating unit, and the heating temperature, and in a case of using an infrared heater, is preferably 1 second to 120 seconds, and more preferably 3 seconds to 90 seconds. In addition, in a case of using a hot air drying furnace, the drying time is preferably 1 hour to 14 hours, and more preferably 2 hours to 10 hours.

### (Surface Treatment)

Since the adhesiveness between the molded body and the metal layer or the other layer can be further improved, it is preferable to perform a surface treatment on the molded body. Examples of the surface treatment include a glow discharge treatment, an ultraviolet irradiation treatment, a corona treatment, a flame treatment, and an acid or alkali treatment. The glow discharge treatment as mentioned herein may be a treatment with a low-temperature plasma generated in a gas at a low pressure ranging from 10⁻³ Torr to 20 Torr, and is preferably a plasma treatment under atmospheric pressure.

The glow discharge treatment is performed using a plasma-excited gas. The plasma-excited gas refers to a gas that is plasma-excited under the above-described conditions, and examples thereof include fluorocarbons such as argon, helium, neon, krypton, xenon, nitrogen, carbon dioxide, and tetrafluoromethane, and mixtures of these.

It is also effective to perform an aging treatment at a temperature equal to or lower than the glass transition temperature of the raw material in order to improve the mechanical properties, the thermal dimensional stability, or the winding shape of the wound molded body.

In addition, after the film forming step, the molded body may be further subjected to a step of narrowing the molded body and/or a step of stretching the molded body by a heating roll to further improve the smoothness of the molded body.

In the above-described manufacturing method, a case where the molded body is a single layer has been described, but the molded body may have a laminated structure in which a plurality of layers are laminated.

### <Step B>

The step B is a step of producing a film having a layer A and a layer B by forming a layer B on the molded body (layer A) produced in the step A using the composition for forming a layer B.

Examples of the step B include a step of applying the composition for forming a layer B onto at least one surface of the molded body produced in the step A, and drying and/or curing the coating film as necessary to form a layer B on the molded body.

Examples of the composition for forming the layer B include a composition including the polymer and the reactive compound.

The solvents may be used alone or in two or more kinds thereof.

A content of the solvent included in the composition for forming a layer B is preferably 0.02% by mass or less and more preferably 0.01% by mass or less with respect to the total mass of the composition for forming a layer B. The lower limit value thereof is not particularly limited and may be 0% by mass.

The content of the solid content of the composition for forming a layer B is preferably 99.98% by mass or more and more preferably 99.99% by mass with respect to the total mass of the composition for forming a layer B. The upper limit value thereof is not particularly limited and may be 100% by mass.

In the present disclosure, the “solid content” of the composition means a component excluding a solvent and water.

A method of applying the composition for forming a layer B onto the molded body (the layer A) is not particularly limited, and examples thereof include a bar coating method, a spray coating method, a slide coating method, a flow coating method, a spin coating method, a dip coating method, a die coating method, an ink jet method, and a curtain coating method.

In a case where the composition for forming the layer B applied onto the molded body (the layer A) is dried, the drying conditions are not particularly limited, but the drying temperature is preferably 25° C. to 200° C., and the drying time is preferably 1 second to 120 minutes.

In addition, in a case of producing a film having the layer C, the layer A, and the layer B in this order, the layer C can be formed on the molded body (the layer A) after forming the layer B on the molded body (the layer A), by using the composition for forming the layer C in the same manner as the method for forming the layer B.

### [Laminate]

The laminate according to the embodiment of the present disclosure may be a laminate in which the film according to the embodiment of the present disclosure is laminated, but is preferably a laminate including the film according to the embodiment of the present disclosure and a metal layer disposed on at least one surface of the film.

Examples of the layer configuration of the laminate according to the present disclosure include the following aspects.
Layer A/layer B/metal layer
Layer B/layer A/metal layer
Layer C/layer A/layer B/metal layer
Layer B/layer A/layer C/metal layer
Metal layer/layer A/layer B/metal layer
Metal layer/layer C/layer A/layer B/metal layer

The metal layer may be disposed only on one surface of the film or may be disposed on both surfaces of the film. In addition, the metal layer may be disposed on the surface of the film directly or via another layer.

Among these, in a case where the metal layer is disposed only on one surface of the film, it is preferable that the layer configuration of the laminate according to the embodiment of the present disclosure is a layer configuration in which the layer B is the outermost layer.

In a case where the laminate according to the present disclosure includes two metal layers, the two metal layers may be metal layers having the same material, thickness, and shape, or may be metal layers having different materials, thicknesses, and shapes.

The laminate according to the present disclosure can be manufactured, for example, by attaching a metal substrate to at least one surface of the film according to the present disclosure. A method of bonding the film according to the present disclosure and the metal substrate is not particularly limited, and a known laminating method can be used.

The metal layer is preferably a copper layer. The copper substrate used for forming the copper layer is preferably a rolled copper foil formed by a rolling method or an electrolytic copper foil formed by an electrolytic method.

An average thickness of the metal layer, preferably the copper layer, is not particularly limited, but is preferably 2 μm to 30 μm, more preferably 3 μm to 20 μm, and still more preferably 5 μm to 18 μm. The copper foil may be copper foil with a carrier formed on a support (carrier) so as to be peelable. As the carrier, a known carrier can be used. An average thickness of the carrier is not particularly limited, but is preferably 10 μm to 100 μm and more preferably 18 μm to 50 μm.

The surface asperity Ra of the metal layer is preferably 1.0 μm or less and more preferably 0.5 μm or less. In a case where the surface asperity Ra is 1.0 μm or less, the surface electrical resistance at the interface between the film and the metal layer is reduced.

The surface asperity Ra in the present disclosure is calculated using a surface asperity meter, for example, a stylus type surface asperity meter “SURFCORDER SE3500” manufactured by Kosaka Laboratory Ltd., and is calculated based on the calculation method of the arithmetic average surface asperity Ra in JIS B0601:2013.

Furthermore, in the measurement of the surface asperity Ra mentioned above, after removing the metal layer in the laminate by etching with a ferric chloride solution, the surface roughness Ra of the film surface, which was in contact with the metal layer and onto which the surface roughness of the metal layer was transferred, is measured and considered as the surface asperity Ra of the metal layer.

### [Wiring Board]

The wiring board according to the present disclosure is preferably a wiring board including the film according to the present disclosure, a metal wire disposed on one surface of the film, and a metal layer disposed on the other surface of the film.

Examples of the layer configuration of the wiring board according to the present disclosure include the following aspects.
Metal layer/layer A/layer B/metal wire
Metal layer/layer B/layer A/metal wire
Metal layer/layer C/layer A/layer B/metal wire
Metal layer/layer B/layer A/layer C/metal wire

The metal layer and the metal wire may be disposed on the surface of the film directly or via other layers.

Among these, the metal wire is preferably disposed on the layer B in a film in which the layer B is the outermost layer.

The metal wire according to the embodiment of the present disclosure can be formed, for example, by attaching a metal substrate to both surfaces of the film according to the embodiment of the present disclosure and then performing an etching treatment on one metal layer by a known method.

The metal layer is preferably a copper layer. The metal wire is preferably a copper wire. The copper substrate used for forming the copper layer and the copper wire is preferably a rolled copper foil formed by a rolling method or an electrolytic copper foil formed by an electrolytic method.

An average thickness of the metal layer, preferably the copper layer, is not particularly limited, but is preferably 2 μm to 30 μm, more preferably 3 μm to 20 μm, and still more preferably 5 μm to 18 μm. The copper foil may be copper foil with a carrier formed on a support (carrier) so as to be peelable. As the carrier, a known carrier can be used. An average thickness of the carrier is not particularly limited, but is preferably 10 μm to 100 μm and more preferably 18 μm to 50 μm.

The average thickness of the metal wire, preferably the copper wire, is not particularly limited, but is preferably 2 μm to 30 μm, more preferably 3 μm to 20 μm, and still more preferably 5 μm to 18 μm.

### [Multilayer Wiring Board]

The laminated wiring board according to the embodiment of the present disclosure preferably includes, in this order, a first metal layer, a film (first film) according to the embodiment of the present disclosure, a metal wire, a film (second film) according to the embodiment of the present disclosure, and a second metal layer, wherein the metal wire is embedded in a part of the first film and the second film.

Since the film according to the embodiment of the present disclosure has excellent step followability, the laminated wiring board according to the embodiment of the present disclosure is unlikely to have a gap between the film and the metal wire, and has a small transmission loss.

It is preferable that the layer A and layer B included in the first film are formed in the order of layer B and then layer A from the side in contact with the metal wire. In addition, it is preferable that the layer A and layer B included in the second film are formed in the order of layer B and then layer A from the side in contact with the metal wire.

In addition, in a case where the first film includes the above-described layer C, it is preferable that the layer A, the layer B, and the layer C included in the first film are formed in the order of the layer B, the layer A, and then the layer C from the side in contact with the metal wire. In a case where the second film includes the above-described layer C, it is preferable that the layer A, the layer B, and the layer C included in the first film are formed in the order of the layer B, the layer A, and then the layer C from the side in contact with the metal wire.

In a case where the layer B is formed on the side in contact with the metal wire, it is preferable that the metal wire is embedded in the layer B of each of the first film and the second film. In addition, the metal wire may be embedded in the layer B of each of the first film and the second film and may be further embedded in the layer A.

The details of the first metal layer and the second metal layer are as described in the section of the laminate.

The details of the first film and the second film are as described in the column of the film.

The details of the metal wire are as described in the section of the wiring board.

### [Manufacturing Method of Laminated Wiring Board]

It is preferable that the method of manufacturing a laminated wiring board according to the embodiment of the present disclosure includes a step of manufacturing a laminate including a film (a first film) according to the embodiment of the present disclosure and a first metal layer disposed on one surface of the first film; a step of manufacturing a wiring board including a film (a second film) according to the embodiment of the present disclosure, a metal wire disposed on one surface of the second film, and a second metal layer disposed on the other surface of the second film; and a step of superimposing the laminate and the wiring board such that both the first metal layer and the second metal layer are outermost surfaces and subjecting the laminate and the wiring board to thermal compression bonding.

The details of the step of manufacturing the laminate are as described in the section of the laminate.

The details of the step of manufacturing the wiring board are as described in the section of the wiring board.

The method and conditions for thermal compression bonding the laminate and the substrate with wire are not particularly limited, and are appropriately selected from known methods and conditions. Among these, the temperature of the thermal compression bonding is preferably 100° C. to 300° C. and more preferably 140° C. to 200° C. The pressure of the thermal compression bonding is preferably 0.1 MPa to 20 MPa. A treatment time of the thermal compression bonding is preferably 0.001 hours to 1.5 hours.

### EXAMPLES

Hereinafter, the present disclosure will be described in more detail with reference to examples. The materials, the used amounts, the proportions, the treatment contents, the treatment procedures, and the like described in the following examples can be appropriately changed without departing from the gist of the present disclosure. Therefore, the scope of the present disclosure is not limited to the following specific examples.

In addition, in the present examples, unless otherwise specified, “%” and “part” mean “% by mass” and “part by mass” respectively.

### <Raw Material for Forming Layer A>

LCP1: Liquid crystal polymer (product name “Zydar LF31”, manufactured by ENEOS Corporation)
LCP2: liquid crystal polymer (product name “LAPEROS A-950”, manufactured by Polyplastics Co., Ltd.)
PE1: Low density polyethylene (product name “NOVATEC LD”, manufactured by Japan Polyethylene Corporation)
Compatibilizer: epoxy group-containing polyolefin-based copolymer (product name “BONDFAST E”, manufactured by Sumitomo Chemical Co., Ltd.)
PI4: Polyimide (product name “Kapton EN”, manufactured by Toray Industries, Inc.)

### <Composition for Forming Layer B and Composition for Forming Layer C>

PI3: Polyimide (product name “PIAD200”, manufactured by Arakawa Chemical Industries, Ltd.)
SEBS: styrene-ethylene-butylene-styrene copolymer (product name “Tuftec M1913”, manufactured by Asahi Kasei Corporation)
PE2: (product name “NOVATEC HD”, manufactured by Japan Polyethylene Corporation).
Epoxy compound: N,N-diglycidyl-4-glycidyloxyaniline (manufactured by Sigma-Aldrich Co., LLC)
Silica particles: product name “ADMAFINE”, manufactured by Admatechs Co., Ltd.
Solvent: toluene

### Example 1

### [Preparation of Layer A]

The LCP1, the PE1, and the compatibilizer were supplied into the cylinder of a single-screw extruder with a screw diameter of 60 mm from the feed port and then subjected to heated kneading. The molten raw material was extruded from a die with a width of 750 mm onto a rotating cast roll to form a film, which was then cooled and solidified, and optionally stretched to produce a molded body with a thickness of 40 μm.

The content of the LCP1 in the raw material was 85% by mass, the content of the PE1 was 12% by mass, and the content of the compatibilizer was 3% by mass.

The temperature of heating and kneading, the discharge rate in a case of discharging the raw material, the clearance of the die lip, and the circumferential speed of the cast roll were each adjusted in the following ranges.
Temperature of heating and kneading: 270° C. to 350° C.
Clearance: 0.01 to 5 mm
Discharge rate: 0.1 to 1,000 mm/sec
Circumferential speed of cast roll: 0.1 to 50 m/min

Next, the obtained molded body was introduced into a hot air drying furnace set at 270° C. and heated for 10 hours to perform an annealing treatment on the molded body.

The molded body subjected to the annealing treatment was transported while being guided by a roller, taken up by a nip roller, and a molded body (layer A) was obtained.

The molded body (layer A) was subjected to corona treatment on both surfaces under a discharge amount of 1500 W·min/m².

### [Formation of Layer B]

PI3, an epoxy compound, and a solvent were mixed and stirred to obtain a composition B1. The amount of the solvent was adjusted so that the concentration of solid contents was 15% by mass. The content of the epoxy compound was adjusted to 5% by mass of the solid content of the composition B1, and it was described in Table 1 as “Epoxy (5)”.

The obtained composition B1 was applied onto one surface of the molded body (layer A) subjected to the corona treatment using an applicator (clearance: 250 μm) to form a coating film. The coating film was dried under the conditions of 130° C. and 1 hour. The application of the composition B1 and the drying of the coating film were repeated to form a layer B having a thickness of 5 μm.

### [Formation of Layer C]

PI3, an epoxy compound, and a solvent were mixed and stirred to obtain a composition C1 in the same manner as the composition B1. The obtained composition C1 was applied onto a surface of the molded body (layer A) subjected to a corona treatment opposite to a side where the layer B was formed, using an applicator (clearance: 250 μm), to form a coating film. The coating film was dried under the conditions of 130° C. and 1 hour. The application of the composition C1 and the drying of the coating film were repeated to form a layer C having a thickness of 5 μm. As a result, a film precursor having the layer C, the layer A, and the layer B in this order was obtained.

Two film precursors were prepared.

### [Production of Laminate (Single-Sided Copper-Clad Laminate)]

A copper foil (thickness: 18 μm, surface asperity Ra: 0.9 μm) was bonded to a surface of the film precursor on the layer C side, and the copper foil was pressure-bonded for 1 hour under conditions of 180° C. and 2 MPa using a thermal press machine (manufactured by Toyo Seiki Seisaku-sho, Ltd.), thereby manufacturing a laminate (single-sided copper-clad laminate). The produced laminate is a laminate having a film having a layer C, a layer A, and a layer B in this order, and a copper layer disposed on the layer C of the film.

### [Production of Laminate (Double-Sided Copper-Clad Laminate)]

In addition, a rolled copper foil (thickness: 18 μm, surface asperity: Ra 0.9 μm) was bonded to both surfaces (surface on the layer A side, surface on the layer C side) of the film precursor, and the film precursor was pressed for 1 hour under conditions of 180° C. and 2 MPa using a thermal press machine (manufactured by Toyo Seiki Seisaku-sho, Ltd.), thereby manufacturing a laminate (double-sided copper-clad laminate). The produced laminate is a laminate having a film having a layer C, a layer A, and a layer B in this order, and a copper layer disposed on each of the layer A and the layer C of the film.

### [Production of Wiring Board]

A mask layer was laminated on a surface of the copper layer disposed on the layer B side of the film in the double-sided copper-clad laminate, and the mask layer was exposed in a patterned manner and then developed to form a mask pattern. Only the surface on the mask pattern side was immersed in a 40% iron (III) chloride aqueous solution (manufactured by Fujifilm Wako Pure Chemical Corporation, first grade), the copper layer on which the mask pattern was not laminated was subjected to an etching treatment, and the mask pattern was peeled off to form a copper wire (microstrip line). The size of the copper wire was a length of 10 cm and a width of 100 μm, and the wire distance was 100 μm. As a result, a wiring board including a film having the layer C, the layer A, and the layer B in this order, a copper layer disposed on the layer C of the film, and a copper wire disposed on the layer B of the film was obtained.

### [Preparation of Laminated Wiring Board]

The laminate (single-sided copper-clad laminate) and the wiring board were superimposed on each other, and thermal compression bonding was performed for 3 minutes under the conditions of 180° C. and 4 MPa. In this case, the copper layer of the laminate (single-sided copper-clad laminate) and the copper layer of the wiring board were laminated so that both of them were on the outermost surface. As a result, a laminated wiring board having the copper layer, the film (the layer C, the layer A, and the layer B are laminated in this order), the copper wire, the film (the layer B, the layer A, and the layer C are laminated in this order), and the copper layer in this order was obtained. The copper wire was embedded in a part of the two films.

### Examples 3, 5 to 8, 11, and 12

A laminated wiring board was obtained by the same method as in Example 1, except that the type of raw material for forming the layer A, the type of component in the composition for forming the layer B, and the thicknesses of the layer A and the layer B were changed to those shown in Table 1.

### Example 2

A laminated wiring board was manufactured by the same method as in Example 1, except that the formation of the layer B was changed to a method shown below.

In the formation of the layer B, the PI, the epoxy compound, and the solvent were mixed and stirred to obtain a composition B2. The amount of the solvent was adjusted so that the concentration of solid contents was 15% by mass. The content of the epoxy compound was adjusted to 15% by mass of the solid content of the composition B2, and it is described as “Epoxy (15)” in Table 1.

### Example 4

A laminated wiring board was manufactured by the same method as in Example 1, except that the formation of the layer B was changed to a method shown below.

In the formation of the layer B, the PI3, the epoxy compound, the silica particles, and the solvent were mixed and stirred to obtain a composition B3. The amount of the solvent was adjusted so that the concentration of solid contents was 15% by mass. The content of the epoxy compound was adjusted to 5% by mass of the solid content of the composition B3, and the content of the silica particles was adjusted to 20% by mass of the solid content of the composition B3.

### Example 9 and Example 10

A laminated wiring board was manufactured by the same method as in Example 1, except that the layer C was not formed.

First, a film precursor having the layers A and B was obtained without forming the layer C.

A laminate (single-sided copper-clad laminated plate) having a film having a layer A and a layer B and a copper layer disposed on the layer A of the film was obtained.

In addition, a laminate (double-sided copper-clad laminated plate) having a film having a layer A and a layer B and a copper layer disposed on each of the layer A and the layer B of the film was obtained.

Further, a wiring board including the film having the layer A and the layer B in this order, the copper layer disposed on the layer A of the film, and the copper wire disposed on the layer B of the film was obtained.

A laminated wiring board having a copper layer, a film (layer A and layer B are laminated in this order), a copper wire, a film (layer B and layer A are laminated in this order), and a copper layer in this order was obtained. The copper wire was embedded in a part of the two films.

### Comparative Examples 1 to 3

In Comparative Examples 1 to 3, a film precursor having only a layer A was obtained by the same method as in Example 1. However, the adhesiveness between the film precursor and the metal layer was insufficient, the wiring work could not be performed, and the evaluation of the step followability and the wiring deviation could not be performed. Therefore, in Table 1, “−” is described in the columns of the step followability and the wiring deviation.

In Comparative Example 1, in a case where the film precursor and the rolled copper foil were bonded to each other at 320° C., wiring processing could be performed, but distortion occurred in the wiring.

### Comparative Example 4

A laminated wiring board was manufactured by the same method as in Example 1, except that the formation of the layer B was changed to a method shown below.

PE2 and a solvent were mixed and stirred to obtain a composition B4 in the formation of the layer B. The amount of the solvent was adjusted so that the concentration of solid contents was 15% by mass.

### Comparative Example 5

A laminated wiring board was manufactured by the same method as in Example 1, except that the formation of the layer A and the layer B was changed to a method shown below.

In the formation of the layer A, PI4 was used as a raw material for forming the layer A.

In the formation of the layer B, a bonding sheet (product name “NIKAFLEX”, manufactured by Nikkan Kogyo Co., Ltd., [BS] in Table 1) was used.

Using the produced laminate and the laminated wiring board, the elastic modulus of the layer A and the layer B at 160° C. and the dielectric loss tangent of the film were measured, and the evaluation of the step followability, the wiring deviation, and the adhesiveness was performed. The measuring method and the evaluation method are as follows.

### <Elastic Modulus of Layer a and Layer B at 160° C.>

The produced laminate was cut along the thickness direction to obtain a cut surface. In the cut surface of the laminate, an elastic modulus at an intermediate position in a thickness direction of each layer from one surface toward the other surface was measured by a nanoindentation method while heating the laminate to 160° C. using a heater attached to the following nanoindenter.

The elastic modulus was measured at each position using a nanoindenter (“TI-950”, manufactured by Hysitron, Inc.) and a Berkovich indenter under the conditions of a load of 500 μN, a loading time of 10 seconds, a holding time of 5 seconds, and an unloading time of 10 seconds, with 10 measurements taken at each position. An arithmetic average value of the ten points was taken as the elastic modulus (unit: MPa) for each position.

### <Dielectric Loss Tangent of Film>

A laminate (single-sided copper-clad laminate) was immersed in a 40% aqueous iron (III) chloride solution (manufactured by FUJIFILM Wako Pure Chemical Corporation, grade 1) and the metal layer was dissolved by an edging treatment to obtain a film.

The dielectric loss tangent was measured by a resonance perturbation method at a frequency of 10 GHz. A 10 GHz cavity resonator (CP531 of Kanto Electronics Application & Development Inc.) was connected to a network analyzer (“E8363B” manufactured by Agilent Technology), the film (width: 2.0 mm×length: 80 mm) was inserted into the cavity resonator, and the dielectric loss tangent of the film was measured based on a change in resonance frequency for 96 hours before and after the insertion in an environment of a temperature of 25° C. and a humidity of 60% RH.

### <Step Followability>

The laminated wiring board was cut along the thickness direction with a microtome, and a cross section was observed with an optical microscope. It was visually observed whether or not there was a gap between the copper wire and the film. In addition, the step followability was evaluated for the thickness of the layer A in the laminate (double-sided copper-clad laminate) based on the dimensional change degree before the preparation of the laminated wiring board and the dimensional change degree after the preparation of the laminated wiring board. The evaluation standards are as follows.

Dimensional change degree=absolute value of {[thickness of layer A in laminate (double-sided copper-clad laminate)]−[thickness of the layer A after manufacturing laminated wiring board]}
A: There is no gap between the copper wire and the film, and the dimensional change degree is 2 μm or less.
B: There is no gap between the copper wire and the film, and the dimensional change degree is 2 μm or more and 5 μm or less.
C: There is a gap between the copper wire and the film.

### <Wiring Deviation>

The laminated wiring board was cut in a state of including the lamination direction and a cross section perpendicular to a longitudinal direction of each copper wire. The obtained cut surface was observed with an optical microscope (“VHX8000” manufactured by Keyence Corporation).

Wiring deviation was evaluated based on a distance M between the center position of the laminated wiring board in the lamination direction and the position of the copper wire. The position of the copper wire means a center position of the copper wire in a thickness direction. The evaluation standards are as follows.
A: The distance M is 1 μm or less.
B: The distance M is 1 μm or more and 3 μm or less.
C: The distance M is 3 μm or more and 10 μm or less.
D: The orientations of the plurality of copper wirings are random.

### <Adhesiveness>

A peeling test piece having a width of 1.0 cm was prepared from the laminate (single-sided copper-clad laminate), the film was fixed in a planar shape with a double-sided adhesive tape, and the strength (peeling strength) in a case where the film was peeled from the metal layer at a rate of 50 mm/min by a 180° method according to JIS C 5016 (1994) was measured. The adhesiveness was evaluated based on the peel strength.
A: The peel strength is 9 N/cm or more.
B: The peel strength is 7 N/cm or more and less than 9 N/cm.
C: The peel strength is 1 N/cm or more and less than 7 N/cm.
D: The peel strength is less than 1 N/cm.

The measurement results and the evaluation results are listed in Table 1.

TABLE 1

| | Layer A | | Layer B | | Layer C | | | | | Dielec- | Evaluation | | |
|---|---|---|---|---|---|---|---|---|---|---|---|---|---|
| | | Thick- | | Thick- | | Thick- | Elastic modulus | | | tric | Step | Wiring | |
| | Compo- | ness | Compo- | ness | Compo- | ness | EA | EB | | loss | follow- | devi- | Adhe- |
| | sition | μm | sition | μm | sition | μm | Gpa | Gpa | EB/EA | tangent | ability | ation | siveness |
| Example | LCP1 + | 40 | PI3 + | 5 | PI3 + | 5 | 0.45 | 1.5 × 10 [symbol] | 3.3 × 10 [symbol] | 1.3 × 10 [symbol] | B | A | B |
| 1 | PE1 | | epoxy (5) | | epoxy (5) | | | | | | | | |
| Example | LCP1 + | 40 | PI3 + | 5 | PI3 + | 5 | 0.45 | 0.03 | 6.7 × 10 [symbol] | 1.6 × 10 [symbol] | B | A | A |
| 2 | PE1 | | epoxy (15) | | epoxy (15) | | | | | | | | |
| Example | LCP1 + | 40 | SEBS + | 5 | SEBS + | 5 | 0.45 | 1.0 × 10 [symbol] | 2.2 × 10 [symbol] | 1.1 × 10 [symbol] | B | A | B |
| 3 | PE1 | | epoxy (5) | | epoxy (5) | | | | | | | | |
| Example | LCP1 + | 40 | PI3 + | 5 | PI3 + | 5 | 0.45 | 0.2 | 4.4 × 10 [symbol] | 1.4 × 10 [symbol] | B | B | B |
| 4 | PE1 | | epoxy (5) + | | epoxy (5) + | | | | | | | | |
| | | | silica | | silica | | | | | | | | |
| | | | particle | | particle | | | | | | | | |
| Example | LCP1 | 40 | PI3 + | 5 | PI3 + | 5 | 0.5 | 1.5 × 10 [symbol] | 3.0 × 10 [symbol] | 1.0 × 10 [symbol] | B | B | B |
| 5 | | | epoxy (5) | | epoxy (5) | | | | | | | | |
| Example | LCP2 | 40 | PI3 + | 5 | PI3 + | 5 | 0.5 | 1.5 × 10 [symbol] | 3.0 × 10 [symbol] | 1.9 × 10 [symbol] | B | B | B |
| 6 | | | epoxy (5) | | epoxy (5) | | | | | | | | |
| Example | LCP1 + | 40 | PI3 + | 9 | PI3 + | 1 | 0.45 | 1.5 × 10 [symbol] | 3.3 × 10 [symbol] | 1.3 × 10 [symbol] | B | B | B |
| 7 | PE1 | | epoxy (5) | | epoxy (5) | | | | | | | | |
| Example | LCP1 + | 40 | PI3 + | 1 | PI3 + | 9 | 0.45 | 1.5 × 10 [symbol] | 3.3 × 10 [symbol] | 1.3 × 10 [symbol] | B | B | B |
| 8 | PE1 | | epoxy (5) | | epoxy (5) | | | | | | | | |
| Example | LCP1 + | 40 | PI3 + | 20 | — | — | 0.45 | 1.5 × 10 [symbol] | 3.3 × 10 [symbol] | 1.8 × 10 [symbol] | A | C | B |
| 9 | PE1 | | epoxy (5) | | | | | | | | | | |
| Example | LCP1 + | 40 | PI3 + | 15 | — | — | 0.45 | 1.5 × 10 [symbol] | 3.3 × 10 [symbol] | 1.6 × 10 [symbol] | B | C | B |
| 10 | PE1 | | epoxy (5) | | | | | | | | | | |
| Example | LCP1 + | 40 | PI3 + | 5 | PI3 + | 20 | 0.45 | 1.5 × 10 [symbol] | 3.3 × 10 [symbol] | 1.9 × 10 [symbol] | A | B | B |
| 11 | PE1 | | epoxy (5) | | epoxy (5) | | | | | | | | |
| Example | LCP1 + | 40 | PI3 + | 5 | PI3 + | 15 | 0.45 | 1.5 × 10 [symbol] | 3.3 × 10 [symbol] | 1.8 × 10 [symbol] | A | B | B |
| 12 | PE1 | | epoxy (5) | | epoxy (5) | | | | | | | | |
| Compar- | LCP1 | 50 | — | — | — | — | 0.5 | — | — | 7.0 × 10 [symbol] | — | — | D |
| ative | | | | | | | | | | | | | |
| Example 1 | | | | | | | | | | | | | |
| Compar- | LCP2 | 50 | — | — | — | — | 0.5 | — | — | 2.0 × 10 [symbol] | — | — | D |
| ative | | | | | | | | | | | | | |
| Example 2 | | | | | | | | | | | | | |
| Compar- | LCP1 + | 50 | — | — | — | — | 0.45 | — | — | 8.0 × 10 [symbol] | — | — | D |
| ative | PE1 | | | | | | | | | | | | |
| Example 3 | | | | | | | | | | | | | |
| Compar- | LCP1 + | 40 | PE2 | 10 | — | — | 0.45 | 3.0 × 10 [symbol] | 6.7 × 10 [symbol] | 8.0 × 10 [symbol] | C | C | C |
| ative | PE1 | | | | | | | | | | | | |
| Example 4 | | | | | | | | | | | | | |
| Compar- | PI4 | 25 | BS | 25 | — | — | 2.5 | 2.0 × 10 [symbol] | 8.0 × 10 [symbol] | 5.2 × 10 [symbol] | B | B | B |
| ative | | | | | | | | | | | | | |
| Example 5 | | | | | | | | | | | | | |

[symbol]

indicates data missing or illegible when filed

As shown in Table 1, it was found that in Examples 1 to 12, since the film includes a layer A; and a layer B disposed on at least one surface of the layer A, in which a ratio of an elastic modulus EB of the layer B at 160° C. to an elastic modulus EA of the layer A at 160° C. is 1.0×10⁻⁶ or more, and a dielectric loss tangent is 0.005 or less, the film has low dielectric properties and excellent step followability.

On the other hand, in Comparative Examples 1 to 3, since the layer B was not included, the wiring processing could not be performed as described above.

In Comparative Example 4, it was found that the ratio of the elastic modulus EB of the layer B at 160° C. to the elastic modulus EA of the layer A at 160° C. was less than 1.0×10⁻⁶, and the step followability was deteriorated.

In Comparative Example 5, the step followability was obtained by using the bonding sheet, but the dielectric loss tangent was extremely high.

The disclosure of Japanese Patent Application No. 2022-087675 filed on May 30, 2022 is incorporated in the present specification by reference. In addition, all documents, patent applications, and technical standards described in the present specification are incorporated herein by reference to the same extent as in a case of being specifically and individually noted that individual documents, patent applications, and technical standards are incorporated by reference.

What is claimed is:

1. A film comprising:
a layer A; and
a layer B disposed on at least one surface of the layer A,
wherein a ratio of an elastic modulus EB of the layer B at 160° C. to an elastic modulus EA of the layer A at 160° C. is 1.0×10⁻⁶ or more, and
a dielectric loss tangent is 0.005 or less.

2. The film according to claim 1,
wherein the elastic modulus EB is 0.1 GPa or less.

3. The film according to claim 1,
wherein the ratio of the elastic modulus EB to the elastic modulus EA is 0.1 or less.

4. The film according to claim 1,
wherein an average thickness of the layer B is 15 μm or less.

5. The film according to claim 1,
wherein the layer A contains a liquid crystal polymer.

6. The film according to claim 1,
wherein a melting point of the layer A is 315° C. or higher.

7. The film according to claim 1,
wherein the layer A contains a polyolefin.

8. The film according to claim 7,
wherein a content of the polyolefin is 5% by mass to 30% by mass with respect to a total mass of the layer A.

9. The film according to claim 1,
wherein the layer B contains a cured substance of a composition containing a polymer and a compound having a reactive group.

10. The film according to claim 1, further comprising:
a layer C,
wherein the layer C, the layer A, and the layer B are arranged in this order.

11. The film according to claim 10,
wherein an average thickness of the layer C is 15 μm or less.

12. The film according to claim 10,
wherein the layer C contains a cured substance of a polymer and a compound having a reactive group.

13. A laminate comprising:
the film according to claim 1; and
a metal layer disposed on at least one surface of the film.

14. A wiring board comprising:
the film according to claim 1;
a metal wire disposed on one surface of the film; and
a metal layer disposed on the other surface of the film.

15. A laminated wiring board comprising, in the following order:
a first metal layer;
a first film according to claim 1;
a metal wire;
a second film according to claim 1; and
a second metal layer,
wherein the metal wire is embedded in a part of the first film and the second film.

16. A manufacturing method of a laminated wiring board, comprising:
manufacturing a laminate including the first film according to claim 1 and a first metal layer disposed on one surface of the first film;
manufacturing a wiring board including the second film according to claim 1, a metal wire disposed on one surface of the second film, and a second metal layer disposed on the other surface of the second film; and
superimposing the laminate and the wiring board such that both the first metal layer and the second metal layer are outermost surfaces and subjecting the laminate and the wiring board to thermal compression bonding.
